(19) United States
(12) Patent Application Publication
(10) Pub. No.: US 2014/0240509 A1
(43) Pub. Date: Aug. 28, 2014

(54) SHORT LIGHT PULSE GENERATION DEVICE, TERAHERTZ WAVE GENERATION DEVICE, CAMERA, IMAGING DEVICE, AND MEASUREMENT DEVICE

(71) Applicant: SEIKO EPSON COPORATION, Tokyo (JP)

(72) Inventor: Hitoshi NAKAYAMA, Chino-shi (JP)

(73) Assignee: SEIKO EPSON COPORATION, Tokyo (JP)

(21) Appl. No.: 14/192,570

(22) Filed: Feb. 27, 2014

(30) Foreign Application Priority Data
Feb. 27, 2013 (JP) 2013-036766

(51) Int. Cl. H01S 5/00; G01N 21/35; H01S 5/34

(52) U.S. Cl. CPC H01S 5/0057; H01S 5/34; G01N 21/3586
USPC 348/162; 372/25; 372/4; 250/338.4

(57) ABSTRACT

A short light pulse generation device includes: a light pulse generation portion that has a quantum well structure and generates a light pulse; a frequency chirping portion that has a quantum well structure and chirps a frequency of the light pulse; a light branching portion that branches a chirped light pulse; and a group velocity dispersion portion that has a plurality of optical waveguides, on which each of a plurality of the light pulses branched in the light branching portion is incident, and produces a group velocity difference depending on a wavelength with respect to a plurality of branched light pulses, wherein light path lengths of the light pulses in a plurality of light paths before the light pulse is branched in the light branching portion and then incident on the plurality of optical waveguides of the group velocity dispersion portion are equal to each other.

### BACKGROUND

1. Technical Field

The present invention relates to a short light pulse generation device, a terahertz wave generation device, a camera, an imaging device, and a measurement device.

2. Related Art

In recent years, terahertz waves which are electromagnetic waves having a frequency equal to or greater than 100 GHz and equal to or less than 30 THz have attracted attention. The terahertz waves can be used in, for example, various types of measurement such as imaging and spectroscopic measurement, non-destructive tests, and the like.

Terahertz wave generation devices that generate terahertz waves include, for example, a short light pulse generation device that generates a light pulse having a pulse width of approximately subpicoseconds (several hundred femtoseconds), and a photoconductive antenna that generates a terahertz wave by irradiation with the light pulse generated in the short light pulse generation device.

As a short light pulse generation device constituting the terahertz wave generation device, for example, JP-A-10-213714 discloses a semiconductor short-pulse laser element provided with a group velocity dispersion compensator.

Here, a group velocity dispersion compensator will be described. When a light pulse is propagated through a medium, the frequency of the light pulse increases over time by a self-phase modulation effect (up-chirp), or the frequency of the light pulse decreases overtime (down-chirp). In this case, when the up-chirped light pulse passes through a medium having negative group velocity dispersion characteristics, the latter half of the light pulse becomes higher in group velocity than the former half thereof, and becomes smaller in pulse width than that. In addition, when the down-chirped light pulse passes through a medium having positive group velocity dispersion characteristics, the latter half of the light pulse becomes higher in group velocity than the former half thereof, and becomes smaller in pulse width than that. In this manner, the group velocity dispersion compensator is used for narrowing a pulse width through group velocity dispersion, that is, performing pulse compression.

However, the group velocity dispersion compensator disclosed in JP-A-10-213714 is not able to control whether the group velocity dispersion compensator has positive group velocity dispersion characteristics or negative group velocity dispersion characteristics. For this reason, in the short light pulse generation device including the group velocity dispersion compensator disclosed in JP-A-10-213714, there is a problem in that a desired pulse width is not obtained. For example, when the group velocity dispersion compensator has positive group velocity dispersion characteristics even though the up-chirped light pulse passes through the group velocity dispersion compensator, the pulse width is expanded. In addition, similarly, when the group velocity dispersion compensator has negative group velocity dispersion characteristics even though the down-chirped light pulse passes through the group velocity dispersion compensator, the pulse width is expanded. In addition, when the group velocity dispersion compensator has both positive group velocity dispersion characteristics and negative group velocity dispersion characteristics, pulse waveforms are distorted, and as a result, a desired pulse width may not be obtained. As mentioned above, in the short light pulse generation device, when the group velocity dispersion characteristics of the group velocity dispersion compensator are not able to be controlled, a desired pulse width may not be obtained.

### SUMMARY

An advantage of some aspects of the invention is to provide a short light pulse generation device capable of obtaining a light pulse having a desired pulse width. Another advantage of some aspects of the invention is to provide a terahertz wave generation device including the short light pulse generation device, a camera, an imaging device, and a measurement device.

An aspect of the invention is directed to a short light pulse generation device including: a light pulse generation portion that has a quantum well structure and generates a light pulse; a frequency chirping portion that has a quantum well structure and chirps a frequency of the light pulse; a light branching portion that branches a chirped light pulse; and a group velocity dispersion portion that has a plurality of optical waveguides, disposed at a mode coupling distance, on which each of a plurality of the light pulses branched in the light branching portion is incident, and produces a group velocity difference depending on a wavelength with respect to a plurality of branched light pulses. Light path lengths of the light pulses in a plurality of light paths before the light pulse is branched in the light branching portion and then incident on the plurality of optical waveguides of the group velocity dispersion portion are equal to each other.

In such a short light pulse generation device, since the light path lengths of a plurality of light pulses before the light pulse is branched in the light branching portion and then incident on the group velocity dispersion portion are equal to each other, the plurality of light pulses which are branched and incident on the group velocity dispersion portion can be set to in-phase. Thereby, the group velocity dispersion portion can have positive group velocity dispersion characteristics. In this manner, according to the short light pulse generation device, since the group velocity dispersion portion can be controlled so as to have positive group velocity dispersion characteristics, it is possible to obtain a light pulse having a desired pulse width.

In the short light pulse generation device, the light branching portion may include: a first semiconductor waveguide which is made of a semiconductor material and on which the chirped light pulse is incident; and a second semiconductor waveguide and a third semiconductor waveguide which are made of the semiconductor material and are branched from the first semiconductor waveguide, and a length of the second semiconductor waveguide and a length of the third semiconductor waveguide may be equal to each other.

In such a short light pulse generation device, the plurality of light pulses which are branched and incident on the group velocity dispersion portion can be set to be in-phase.

Another aspect of the invention is directed to a short light pulse generation device including: a light pulse generation portion that has a quantum well structure and generates a light pulse; a frequency chirping portion that has a quantum well structure and chirps a frequency of the light pulse; a light branching portion that branches a chirped light pulse; and a group velocity dispersion portion that has a plurality of optical waveguides, disposed at a mode coupling distance, on which each of a plurality of the light pulses branched in the light branching portion is incident, and produces a group velocity difference depending on a wavelength with respect to a plurality of branched light pulses. The light branching portion produces a light path difference in the plurality of branched light pulses which are set to have opposite phases to each other and are incident on the group velocity dispersion portion.

In a short light pulse generation device, since the light branching portion produces a light path difference in the plurality of branched light pulses which are set to have opposite phases to each other and are incident on the group velocity dispersion portion, the plurality of light pulses which are branched and incident on the group velocity dispersion portion can be set to have opposite phases. Thereby, the group velocity dispersion portion can have negative group velocity dispersion characteristics. In this manner, according to the short light pulse generation device, since the group velocity dispersion portion can be controlled so as to have negative group velocity dispersion characteristics, it is possible to obtain a light pulse having a desired pulse width.

In the short light pulse generation device, the light branching portion may include: a first semiconductor waveguide which is made of a semiconductor material and on which the chirped light pulse is incident; and a second semiconductor waveguide and a third semiconductor waveguide which are made of the semiconductor material and are branched from the first semiconductor waveguide, and the light path difference may be produced by a difference between a length of the second semiconductor waveguide and a length of the third semiconductor waveguide.

In such a short light pulse generation device, the plurality of light pulses which are branched and incident on the group velocity dispersion portion can be set to have opposite phases.

In the short light pulse generation device, the light branching portion may include: a first semiconductor waveguide which is made of a semiconductor material and on which the chirped light pulse is incident; a second semiconductor waveguide and a third semiconductor waveguide which are made of the semiconductor material and are branched from the first semiconductor waveguide; a first electrode that applies a voltage to the second semiconductor waveguide; and a second electrode that applies a voltage to the third semiconductor waveguide.

In such a short light pulse generation device, it is possible to change the refractive index of a semiconductor layer constituting the second semiconductor waveguide by the first electrode, and to change the refractive index of a semiconductor layer constituting the third semiconductor waveguide by the second electrode. Therefore, it is possible to produce a light path difference in the plurality of branched light pulses which are set to have opposite phases to each other and are incident on the group velocity dispersion portion.

Still another aspect of the invention is directed to a terahertz wave generation device including: the short light pulse generation device according to the above aspect; and a photoconductive antenna that generates a terahertz wave by irradiation with a short light pulse generated in the short light pulse generation device.

In such a terahertz wave generation device, the short light pulse generation device according to the above aspect is included, and thus it is possible to achieve a reduction in the size thereof.

Yet another aspect of the invention is directed to a camera including: the short light pulse generation device according to the above aspect; a photoconductive antenna that generates a terahertz wave by irradiation with a short light pulse generated in the short light pulse generation device; a terahertz wave detection portion that detects the terahertz wave emitted from the photoconductive antenna and passing through an object or the terahertz wave reflected from the object; and a storage portion that stores a detection result of the terahertz wave detection portion.

In such a camera, the short light pulse generation device according to the above aspect is included, and thus it is possible to achieve a reduction in the size thereof.

Still yet another aspect of the invention is directed to an imaging device including: the short light pulse generation device according to the above aspect; a photoconductive antenna that generates a terahertz wave by irradiation with a short light pulse generated in the short light pulse generation device; a terahertz wave detection portion that detects the terahertz wave emitted from the photoconductive antenna and passing through an object or the terahertz wave reflected from the object; and an image forming portion that generates an image of the object on the basis of a detection result of the terahertz wave detection portion.

In such an imaging device, the short light pulse generation device according to the above aspect is included, and thus it is possible to achieve a reduction in the size thereof.

Further another aspect of the invention is directed to a measurement device including: the short light pulse generation device according to the above aspect; a photoconductive antenna that generates a terahertz wave by irradiation with a short light pulse generated in the short light pulse generation device; a terahertz wave detection portion that detects the terahertz wave emitted from the photoconductive antenna and passing through an object or the terahertz wave reflected from the object; and a measurement portion that measures the object on the basis of a detection result of the terahertz wave detection portion.

In such a measurement device, the short light pulse generation device according to the above aspect is included, and thus it is possible to achieve a reduction in the size thereof.

### BRIEF DESCRIPTION OF THE DRAWINGS

The invention will be described with reference to the accompanying drawings, wherein like numbers reference like elements.

FIG. 1 is a perspective view schematically illustrating a short light pulse generation device according to a first embodiment.

FIG. 2 is a plan view schematically illustrating the short light pulse generation device according to the first embodiment.

FIG. 3 is a cross-sectional view schematically illustrating the short light pulse generation device according to the first embodiment.

FIG. 4 is a graph illustrating an example of a light pulse generated in a light pulse generation portion.

FIG. 5 is a graph illustrating an example of chirp characteristics of a frequency chirping portion.

FIG. 6 is a graph illustrating a mode of a light pulse in a group velocity dispersion portion.

FIG. 7 is a graph illustrating an example of a light pulse generated in the group velocity dispersion portion.

FIG. 8 is a cross-sectional view schematically illustrating a process of manufacturing the short light pulse generation device according to the first embodiment.

FIG. 9 is a cross-sectional view schematically illustrating a process of manufacturing the short light pulse generation device according to the first embodiment.

FIG. 10 is a plan view schematically illustrating a short light pulse generation device according to a first modification example of the first embodiment.

FIG. 11 is a cross-sectional view schematically illustrating the short light pulse generation device according to the first modification example of the first embodiment.

FIG. 12 is a plan view schematically illustrating a short light pulse generation device according to a second modification example of the first embodiment.

FIG. 13 is a cross-sectional view schematically illustrating the short light pulse generation device according to the second modification example of the first embodiment.

FIG. 14 is a plan view schematically illustrating a short light pulse generation device according to a third modification example of the first embodiment.

FIG. 15 is a cross-sectional view schematically illustrating the short light pulse generation device according to the third modification example of the first embodiment.

FIG. 16 is a plan view schematically illustrating a short light pulse generation device according to a fourth modification example of the first embodiment.

FIG. 17 is a cross-sectional view schematically illustrating the short light pulse generation device according to the fourth modification example of the first embodiment.

FIG. 18 is a perspective view schematically illustrating a short light pulse generation device according to a fifth modification example of the first embodiment.

FIG. 19 is a plan view schematically illustrating the short light pulse generation device according to the fifth modification example of the first embodiment.

FIG. 20 is a perspective view schematically illustrating a short light pulse generation device according to a second embodiment.

FIG. 21 is a plan view schematically illustrating the short light pulse generation device according to the second embodiment.

FIG. 22 is a graph illustrating a mode of a light pulse in the group velocity dispersion portion.

FIG. 23 is a graph illustrating an example of a light pulse generated in the group velocity dispersion portion.

FIG. 24 is a plan view schematically illustrating a short light pulse generation device according to a first modification example of the second embodiment.

FIG. 25 is a cross-sectional view schematically illustrating the short light pulse generation device according to the first modification example of the second embodiment.

FIG. 26 is a plan view schematically illustrating a short light pulse generation device according to a second modification example of the second embodiment.

FIG. 27 is a cross-sectional view schematically illustrating the short light pulse generation device according to the second modification example of the second embodiment.

FIG. 28 is a diagram illustrating a configuration of a terahertz wave generation device according to a third embodiment.

FIG. 29 is a block diagram illustrating an imaging device according to a fourth embodiment.

FIG. 30 is a plan view schematically illustrating a terahertz wave detection portion of the imaging device according to the fourth embodiment.

FIG. 31 is a graph illustrating a spectrum of an object in a terahertz band.

FIG. 32 is an image diagram illustrating a distribution of substances A, B and C of the object.

FIG. 33 is a block diagram illustrating a measurement device according to a fifth embodiment.

FIG. 34 is a block diagram illustrating a camera according to a sixth embodiment.

FIG. 35 is a perspective view schematically illustrating the camera according to the sixth embodiment.

### DESCRIPTION OF EXEMPLARY EMBODIMENTS

Hereinafter, preferred embodiments of the invention will be described in detail with reference to the accompanying drawings. Meanwhile, note that the embodiments described below do not improperly limit the content of the invention described in the appended claims. In addition, all the configurations described below are not necessarily essential requirements of the invention.

### 1. First Embodiment

### 1.1. Configuration of Short Light Pulse Generation Device

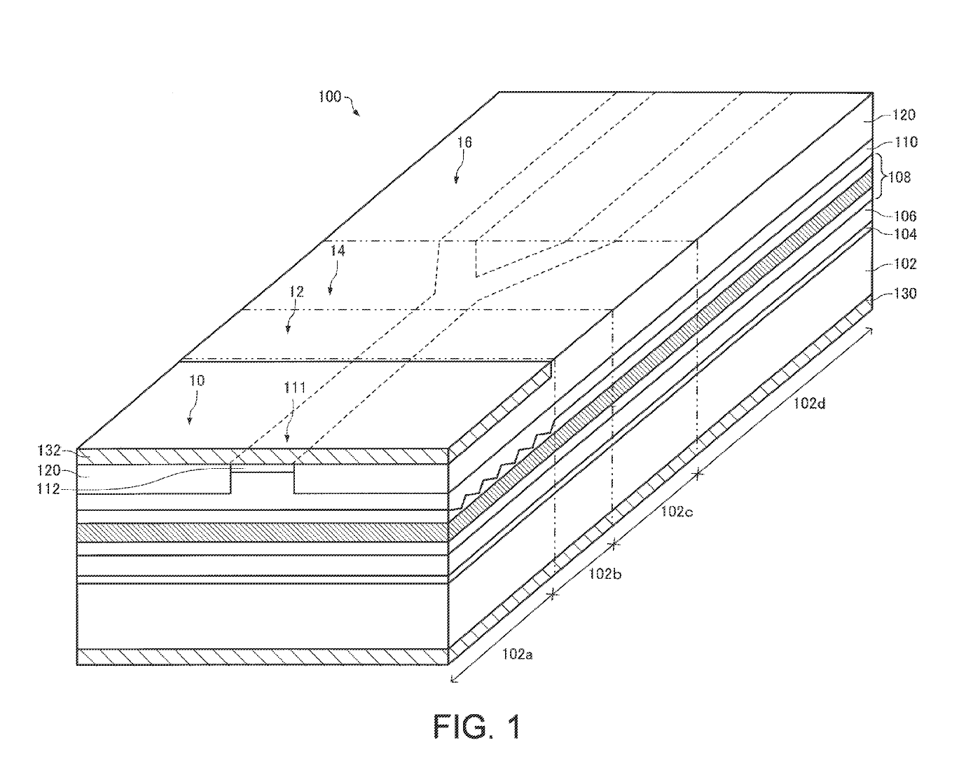

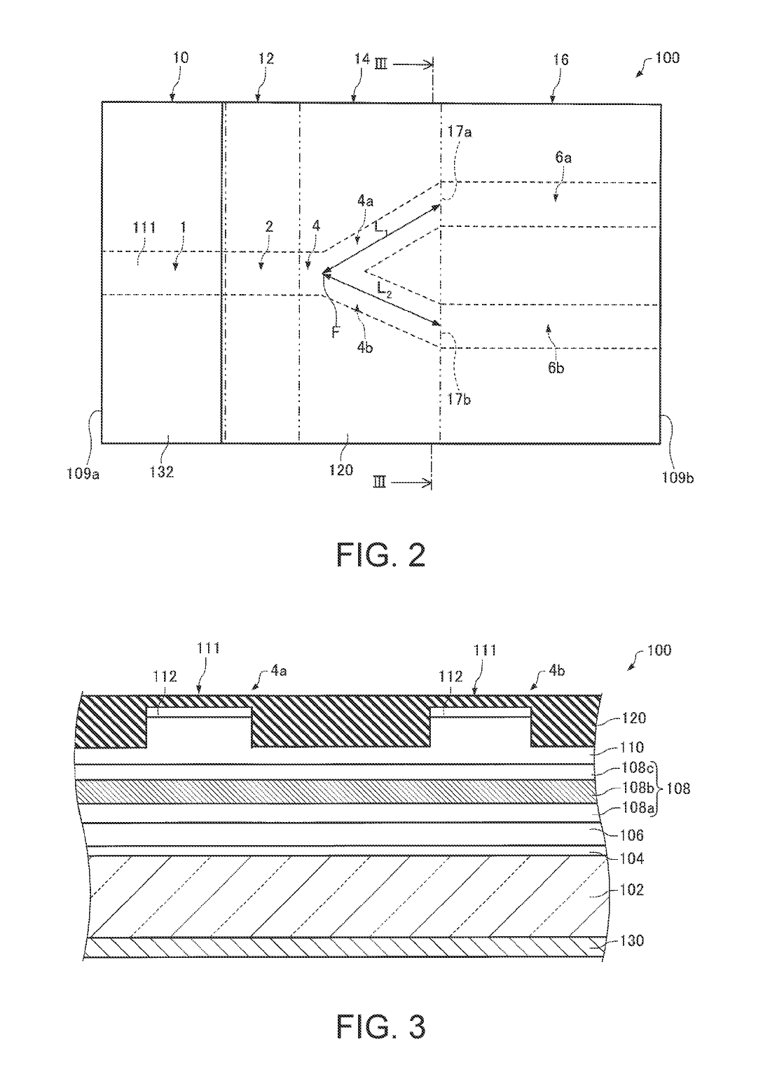

First, a short light pulse generation device 100 according to a first embodiment will be described with reference to the accompanying drawings. FIG. 1 is a perspective view schematically illustrating the short light pulse generation device 100 according to the embodiment. FIG. 2 is a plan view schematically illustrating the short light pulse generation device 100 according to the embodiment.

As shown in FIGS. 1 and 2, the short light pulse generation device 100 includes a light pulse generation portion 10 that generates a light pulse, a frequency chirping portion 12 that chirps a frequency of a light pulse, a light branching portion 14 that branches the chirped light pulse, and a group velocity dispersion portion 16 that produces a group velocity difference depending on wavelengths with respect to a plurality of branched light pulses.

The light pulse generation portion 10 generates a light pulse. The term “light pulse” as used herein refers to light of which the intensity changes drastically in a short period of time. The pulse width (full width at half maximum; FWHM) of the light pulse generated by the light pulse generation portion 10 is not particularly limited, but is, for example, equal to or greater than 1 ps (picosecond) and equal to or less than 100 ps. The light pulse generation portion 10 is, for example, a semiconductor laser having a quantum well structure (core layer 108), and is a DFB (Distributed Feedback) laser in the shown example. Meanwhile, the light pulse generation portion 10 may be, for example, a semiconductor laser such as a DBR laser or a mode-locked laser. In addition, the light pulse generation portion 10 may be, for example, a super-luminescent diode (SLD) without being limited to the semiconductor laser. The light pulse generated in the light pulse generation portion 10 is propagated through an optical waveguide 1 constituted by a first cladding layer 106, a core layer 108, and a second cladding layer 110, and is incident on an optical waveguide 2 of the frequency chirping portion 12.

The frequency chirping portion 12 chirps a frequency of the light pulse generated in the light pulse generation portion 10. The frequency chirping portion 12 is made of, for example, a semiconductor material, and has a quantum well structure. In the shown example, the frequency chirping portion 12 is configured to include the core layer 108 having a quantum well structure. The frequency chirping portion 12 has the optical waveguide 2 connected to the optical waveguide 1. When the light pulse is propagated through the optical waveguide 2, the refractive index of an optical waveguide material changes by an optical Kerr effect, and the phase of an electric field changes (self-phase modulation effect). The frequency of the light pulse is chirped by the self-phase modulation effect. The term “frequency chirp” as used herein refers to a phenomenon in which the frequency of the light pulse changes temporally.

The frequency chirping portion 12 is made of a semiconductor material, and thus shows a slow speed of response to the light pulse having a pulse width of approximately 1 ps to 100 ps. For this reason, in the frequency chirping portion 12, the light pulse is given a frequency chirp (up-chirp or down-chirp) proportional to the intensity (the square of an electric field amplitude) of the light pulse. The term “up-chirp” as used herein refers to a case where the frequency of the light pulse increases over time, and the term “down-chirp” as used herein refers to a case where the frequency of the light pulse decreases over time. In other words, the term “up-chirp” as used herein refers to a case where the wavelength of the light pulse gets shorter over time, and the term “down-chirp” as used herein refers to a case where the wavelength of the light pulse gets longer over time.

The light branching portion 14 branches a light pulse chirped in the frequency chirping portion 12. The light branching portion 14 includes an optical waveguide 4 on which the chirped light pulse is incident and a plurality of (two, in the shown example) optical waveguides 4a and 4b branched from the optical waveguide 4. The optical waveguide 4 and the optical waveguides 4a and 4b are semiconductor waveguides made of a semiconductor material. The optical waveguide 4 is connected to the optical waveguide 2 of the frequency chirping portion 12. The optical waveguide 4a is branched from the optical waveguide 4, and is connected to an optical waveguide 6a of the group velocity dispersion portion 16. In addition, the optical waveguide 4b is branched from the optical waveguide 4, and is connected to an optical waveguide 6b of the group velocity dispersion portion 16.

Here, the length L₁ of the optical waveguide 4a and the length L₂ of the optical waveguide 4b are equal to each other. Meanwhile, as shown in FIG. 2, the length L₁ of the optical waveguide 4a is a distance along the optical waveguide 4a between a branch point F from which the light pulse propagated through the optical waveguide 4 is branched and an incidence plane 17a of the optical waveguide 6a of the group velocity dispersion portion 16. In addition, the length L₂ of the optical waveguide 4b is a distance along the optical waveguide 4b between the branch point F and an incidence plane 17b of the optical waveguide 6b of the group velocity dispersion portion 16. In addition, since the optical waveguide 4a and the optical waveguide 4b are made of the same semiconductor material, the refractive indexes thereof are equal to each other. Therefore, the light path length before the light pulse is branched at the branch point F and then propagated through the optical waveguide 4a to be incident on the optical waveguide 6a (incidence plane 17a) and the light path length before the light pulse is branched at the branch point F and then propagated through the optical waveguide 4b to be incident on the optical waveguide 6b (incidence plane 17b) are equal to each other. The term “light path length” as used herein refers to a product nd when light travels through a medium having a refractive index n along the light path by a distance d. In this manner, in the light branching portion 14, since the light path lengths before the light pulse is branched in the light branching portion 14 and then incident on the group velocity dispersion portion 16 are equal to each other, the light pulse which is propagated through the optical waveguide 4a and incident on the group velocity dispersion portion 16 and the light pulse which is propagated through the optical waveguide 4b and incident on the group velocity dispersion portion 16 are set to be in-phase in the incidence planes 17a and 17b of the group velocity dispersion portion 16. Therefore, the mode of the light pulse in the group velocity dispersion portion 16 is set to an even mode. Thereby, the group velocity dispersion portion 16 can have positive group velocity dispersion characteristics. That is, the group velocity dispersion portion 16 can be used as a normal dispersion medium. The reason will be described in “1.4. Group Velocity Dispersion Characteristics of Group Velocity Dispersion Portion” described later.

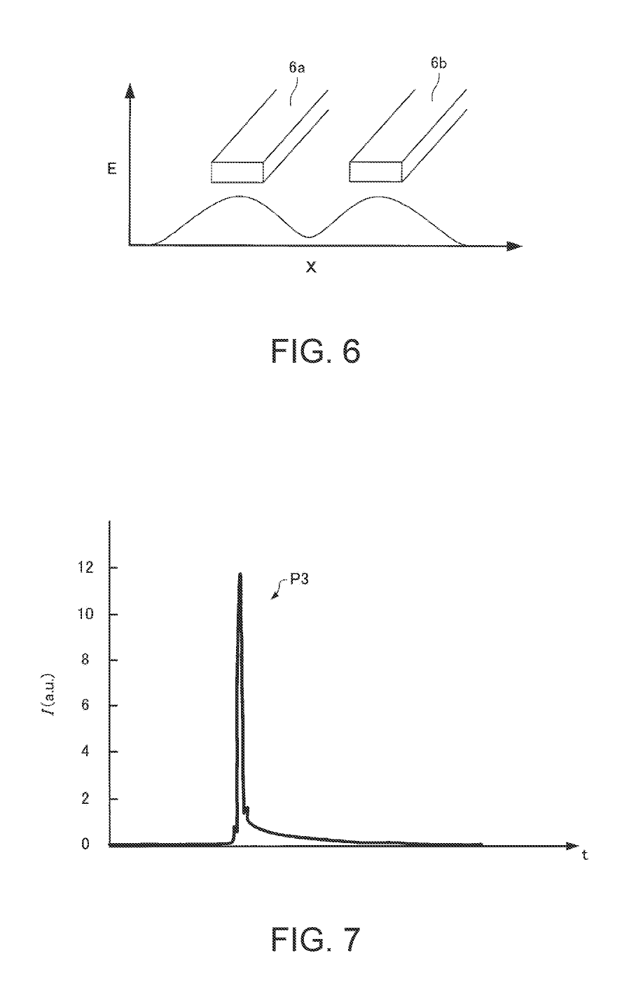

Meanwhile, the term “in-phase” as used herein refers to the phase difference between two light beams being 0 degrees. In addition, the term “even mode” as used herein refers to a mode having an electric field distribution with an in-phase belly (peak) in two optical waveguides (see FIG. 6). That is, in the even mode, the light pulses are propagated with electric fields having the same sign, in the two optical waveguides 6a and 6b of the group velocity dispersion portion 16. In addition, the term “normal dispersion” as used herein refers to a phenomenon in which a refractive index increases as a wavelength gets shorter.

The group velocity dispersion portion 16 produces a group velocity difference depending on wavelengths (frequencies) with respect to the light pulses branched in the light branching portion 14. Specifically, the group velocity dispersion portion 16 can produce a group velocity difference showing a reduction in the pulse width of the light pulse with respect to the chirped light pulse (pulse compression). Since incident light pulses are in-phase, the group velocity dispersion portion 16 has positive group velocity dispersion characteristics. Therefore, in the group velocity dispersion portion 16, positive group velocity dispersion is produced in the down-chirped light pulse, thereby allowing the pulse width to be reduced. In this manner, in the group velocity dispersion portion 16, pulse compression based on the group velocity dispersion is performed. The pulse width of the light pulse compressed in the group velocity dispersion portion 16 is not particularly limited, but is, for example, equal to or greater than 1 fs (femtosecond) and equal to or less than 800 fs.

The group velocity dispersion portion 16 is disposed at a mode coupling distance, and includes a plurality of (two) optical waveguides 6a and 6b on which a plurality of light pulses branched in the light branching portion 14 are respectively incident. That is, the two optical waveguides 6a and 6b constitute a so-called coupled waveguide. Meanwhile, the term “mode coupling distance” as used herein refers to a distance at which light beams propagated through the optical waveguide 6a and optical waveguide 6b can pass back and forth. In the group velocity dispersion portion 16, mode coupling in the two optical waveguides 6a and 6b allows a large group velocity difference to be produced. The optical waveguide 6a of the group velocity dispersion portion 16 is connected to the optical waveguide 4a of the light branching portion 14. The optical waveguide 6b of the group velocity dispersion portion 16 is connected to the optical waveguide 4b of the light branching portion 14.

### 1.2. Structure of Short Light Pulse Generation Device

Next, the structure of the short light pulse generation device 100 will be described. FIG. 3 is a cross-sectional view schematically illustrating the short light pulse generation device 100 according to the embodiment. Meanwhile, FIG. 3 is a cross-sectional view taken along the line III-III of FIG. 2.

As shown in FIGS. 1 to 3, the short light pulse generation device 100 is integrally provided with the light pulse generation portion 10, the frequency chirping portion 12, the light branching portion 14, and the group velocity dispersion portion 16. That is, in the short light pulse generation device 100, the light pulse generation portion 10, the frequency chirping portion 12, the light branching portion 14, and the group velocity dispersion portion 16 are provided on the same substrate 102.

Specifically, the short light pulse generation device 100 is configured to include the substrate 102, a buffer layer 104, the first cladding layer 106, the core layer 108, the second cladding layer 110, a cap layer 112, an insulating layer 120, an electrode 130, and an electrode 132.

The substrate 102 is, for example, a first conductivity-type (for example, n-type) GaAs substrate. As shown in FIG. 1, the substrate 102 includes a first region 102a on which the light pulse generation portion 10 is formed, a second region 102b on which the frequency chirping portion 12 is formed, a third region 102c on which the light branching portion 14 is formed, and a fourth region 102d on which the group velocity dispersion portion 16 is formed.

The buffer layer 104 is provided on the substrate 102. The buffer layer 104 is, for example, an n-type GaAs layer. The buffer layer 104 can improve the crystallizability of a layer formed thereabove.

The first cladding layer 106 is provided on the buffer layer 104. The first cladding layer 106 is, for example, an n-type AlGaAs layer.

The core layer 108 includes a first guide layer 108a, a MQW layer 108b, and a second guide layer 108c.

The first guide layer 108a is provided on the first cladding layer 106. The first guide layer 108a is, for example, an i-type AlGaAs layer.

The MQW layer 108b is provided on the first guide layer 108a. The MQW layer 108b has, for example, a multi-quantum well structure obtained by overlapping three quantum well structures constituted by a GaAs well layer and an AlGaAs barrier layer. In the shown example, the numbers of quantum wells of the MQW layer 108b (the numbers of laminated GaAs well layers and AlGaAs barrier layers) are the same as each other at the side above the first region 102a to the fourth region 102d. That is, in the light pulse generation portion 10, the frequency chirping portion 12, the light branching portion 14, and the group velocity dispersion portion 16, the numbers of quantum wells of the MQW layer 108b are the same as each other. Meanwhile, the number of quantum wells of the MQW layer 108b above the first region 102a, the number of quantum wells of the MQW layer 108b above the second region 102b, the number of quantum wells of the MQW layer 108b above the third region 102c, and the number of quantum wells of the MQW layer 108b above the fourth region 102d may be different from each other. That is, the number of quantum wells of the MQW layer 108b constituting the light pulse generation portion 10, the number of quantum wells of the MQW layer 108b constituting the frequency chirping portion 12, the number of quantum wells of the MQW layer 108b constituting the light branching portion 14, and the number of quantum wells of the MQW layer 108b constituting the group velocity dispersion portion 16 may be different from each other. Meanwhile, the term “quantum well structure” as used herein refers to a general quantum well structure in the field of a semiconductor light emitting device, and is a structure in which a thin film (nm order) made of a material having a small band gap is sandwiched between thin films made of a material having a large band gap using two or more kinds of materials having different band gaps.

The second guide layer 108c is provided on the MQW layer 108b. The second guide layer 108c is, for example, an i-type AlGaAs layer. The second guide layer 108c is provided with a periodic structure constituting a DFB-type resonator. The periodic structure is provided above the first region 102a as shown in FIG. 1. The periodic structure is constituted by two layers (second guide layer 108c and second cladding layer 110) having different refractive indexes.

The core layer 108 through which light (light pulse) produced in the MQW layer 108b is propagated can be constituted by the first guide layer 108a, the MQW layer 108b, and the second guide layer 108c. The first guide layer 108a and the second guide layer 108c are layers used to confine injected carriers (electrons and holes) in the MQW layer 108b and confine light in the core layer 108.

Meanwhile, the core layer 108 may have a quantum well structure (MQW layer 108b) above at least the first region 102a and the second region 102b. For example, the core layer 108 may not have a quantum well structure above the third region 102c and the fourth region 102d. That is, the core layer 108 constituting the light branching portion 14 and the core layer 108 constituting the group velocity dispersion portion 16 may not have a quantum well structure. In that case, the core layer 108 of the light branching portion 14 and the group velocity dispersion portion 16 is, for example, a single layer of an AlGaAs layer.

The second cladding layer 110 is provided on the core layer 108. The second cladding layer 110 is, for example, an AlGaAs layer of a second conductivity-type (for example, p-type).

In the shown example, the optical waveguide 1, the optical waveguide 2, the optical waveguide 4, the optical waveguides 4a and 4b, and the optical waveguides 6a and 6b are constituted by the first cladding layer 106, the core layer 108, and the second cladding layer 110. Each of the optical waveguides 1, 2, 4, 4a, 4b, 6a, and 6b is linearly provided in the shown example. As shown in FIG. 2, the optical waveguides 1, 2, 4, 4a, 4b, 6a, and 6b are continuous from a lateral side 109a of the core layer 108 to a lateral side 109b of the core layer 108.

The optical waveguides 4a and 4b are arranged in a direction perpendicular to the lamination direction of the semiconductor layers 104 to 112. In the shown example, the optical waveguides 4a and 4b are arranged in the in-plane direction of the substrate 102. In the shown example, the width of the optical waveguide 4a and the width of the optical waveguide 4b are the same in size. Meanwhile, the width of the optical waveguide 4a and the width of the optical waveguide 4b may have different sizes.

The optical waveguide 6a and the optical waveguide 6b constitute a coupled waveguide. The optical waveguide 6a and the optical waveguide 6b are arranged in a direction perpendicular to the lamination direction of the semiconductor layers 104 to 112. In the shown example, the optical waveguides 6a and 6b are arranged in the in-plane direction of the substrate 102. In the shown example, the width of the optical waveguide 6a and the width of the optical waveguide 6b are the same in size. Meanwhile, the width of the optical waveguide 6a and the width of the optical waveguide 6b may have different sizes.

In the light pulse generation portion 10, a pin diode is constituted by, for example, the p-type second cladding layer 110, the core layer 108 which is not doped with impurities, and the n-type first cladding layer 106. Each of the first cladding layer 106 and the second cladding layer 110 is a layer having a larger band gap and a smaller refractive index than those of the core layer 108. The core layer 108 has a function of generating light, amplifying the light, and guiding a wave of the light. The first cladding layer 106 and the second cladding layer 110 have a function of confining injected carriers (electrons and holes) and light (function of suppressing the leakage of light) with the core layer 108 interposed therebetween.

In the light pulse generation portion 10, when the forward bias voltage of the pin diode is applied between the electrode 130 and the electrode 132, recoupling between electrons and holes occurs in the core layer 108 (MQW layer 108b). Emitted light is produced by the recoupling. Stimulated emission occurs in a chain reaction manner with the produced light (light pulse) as a starting point, and the intensity of the light (light pulse) is amplified within the optical waveguide 1.

The cap layer 112 is provided on the second cladding layer 110. The cap layer 112 can come into ohmic contact with the electrode 132. The cap layer 112 is, for example, a p-type GaAs layer.

The cap layer 112 and a portion of the second cladding layer 110 constitute a columnar portion 111. For example, in the light pulse generation portion 10, a current path between the electrodes 130 and 132 is determined by the planar shape of the columnar portion 111.

The buffer layer 104, the first cladding layer 106, the core layer 108, the second cladding layer 110, and the cap layer 112 are provided throughout the first region 102a, the second region 102b, the third region 102c, and the fourth region 102d. That is, these layers 104, 106, 108, 110, and 112 are layers common to the light pulse generation portion 10, the frequency chirping portion 12, the light branching portion 14, and the group velocity dispersion portion 16, and are continuous layers.

The insulating layer 120 is provided on the second cladding layer 110 and laterally of the columnar portion 111. Further, the insulating layer 120 is provided on the cap layer 112 located above the second region 102b, the third region 102c, and the fourth region 102d. The insulating layer 120 is, for example, a SiN layer, a SiO₂ layer, a SiON layer, an Al₂O₃ layer, a polyimide layer, or the like.

When the above-mentioned materials are used as the insulating layer 120, a current between the electrodes 130 and 132 can bypass the insulating layer 120 to flow through the columnar portion 111 interposed in the insulating layer 120. In addition, the insulating layer 120 can have a refractive index smaller than the refractive index of the second cladding layer 110. In this case, the effective refractive index of the vertical cross-section of a portion in which the columnar portion 111 is not formed becomes smaller than the effective refractive index of the vertical cross-section of a portion in which the columnar portion 111 is formed. Thereby, light can be efficiently confined within the optical waveguides 1, 2, 4, 4a, 4b, 6a, and 6b in a planar direction. Meanwhile, although not shown, an air layer may be used without using the above-mentioned materials as the insulating layer 120. In this case, the air layer can function as the insulating layer 120.

The electrode 130 is provided throughout the entire surface below the substrate 102. The electrode 130 is in contact with a layer (substrate 102 in the shown example) which comes into ohmic contact with the electrode 130. The electrode 130 is electrically connected to the first cladding layer 106 through the substrate 102. The electrode 130 is one electrode for driving the light pulse generation portion 10. As the electrode 130, for example, a layer or the like having a Cr layer, an AuGe layer, an Ni layer, and an Au layer laminated in this order from the substrate 102 side can be used. Meanwhile, the electrode 130 may be provided only below the first region 102a of the substrate 102.

The electrode 132 is provided on the upper surface of the cap layer 112 and above the first region 102a. Further, the electrode 132 may be provided on the insulating layer 120. The electrode 132 is electrically connected to the second cladding layer 110 through the cap layer 112. The electrode 132 is the other electrode for driving the light pulse generation portion 10. As the electrode 132, for example, a layer or the like having a Cr layer, an AuZn layer, and an Au layer laminated in this order from the cap layer 112 side can be used. Meanwhile, the example shows a double-sided electrode structure in which the electrode 130 is provided on the lower surface side of the substrate 102 and the electrode 132 is provided on the upper surface side of the substrate 102. However, a one-sided electrode structure may be used in which the electrode 130 and the electrode 132 are provided on the same surface side (for example, upper surface side) of the substrate 102.

Herein, as an example of the short light pulse generation device 100 according to the embodiment, a case where an AlGaAs-based semiconductor material is used has been described, but other semiconductor materials such as, for example, AlGaN-based, GaN-based, InGaN-based, GaAs-based, InGaAs-based, InGaAsP-based, and ZnCdSe-based materials may be used without being limited thereto.

Meanwhile, although not shown, an electrode for applying a reverse bias to the frequency chirping portion 12 may be provided. In this case, the insulating layer 120 is not provided on the cap layer 112 of the frequency chirping portion 12, and the electrode for applying a reverse bias to the frequency chirping portion 12 comes into ohmic contact with the cap layer 112. Thereby, it is possible to control the absorption characteristics of the frequency chirping portion 12, and to adjust the amount of frequency chirp.

In addition, an electrode for applying a voltage to the light branching portion 14 may be provided. For example, an electrode for applying a voltage to the optical waveguide 4a of the light branching portion 14 and an electrode for applying a voltage to the optical waveguide 4b of the light branching portion 14 may be provided. In this case, the insulating layer 120 is not provided on the cap layer 112 of the light branching portion 14, and the electrode for applying a voltage to the light branching portion 14 comes into ohmic contact with the cap layer 112. Thereby, it is possible to control the refractive indexes of the optical waveguide 4a and the optical waveguide 4b by a non-linear optical effect, and to control the light path length of the light pulse propagated through the optical waveguide 4a and the light path length of the light pulse propagated through the optical waveguide 4b. Therefore, it is possible to adjust to an optimum light path length by correcting, for example, a variation in light path length caused by a variation in the manufacturing of a device.

In addition, an electrode for applying a voltage to the group velocity dispersion portion 16 may be provided. For example, in the group velocity dispersion portion 16, an electrode for applying a voltage to the optical waveguide 6a and an electrode for applying a voltage to the optical waveguide 6b may be provided. In this case, the insulating layer 120 is not provided on the cap layer 112 of the group velocity dispersion portion 16, and the electrode for applying a voltage to the group velocity dispersion portion 16 comes into ohmic contact with the cap layer 112. Thereby, it is possible to control the amount of group velocity dispersion of the group velocity dispersion portion 16. Therefore, it is possible to adjust to an optimum group velocity dispersion value by correcting, for example, a variation in group velocity dispersion value caused by a variation in the manufacturing of a device.

### 1.3. Operations of Short Light Pulse Generation Device

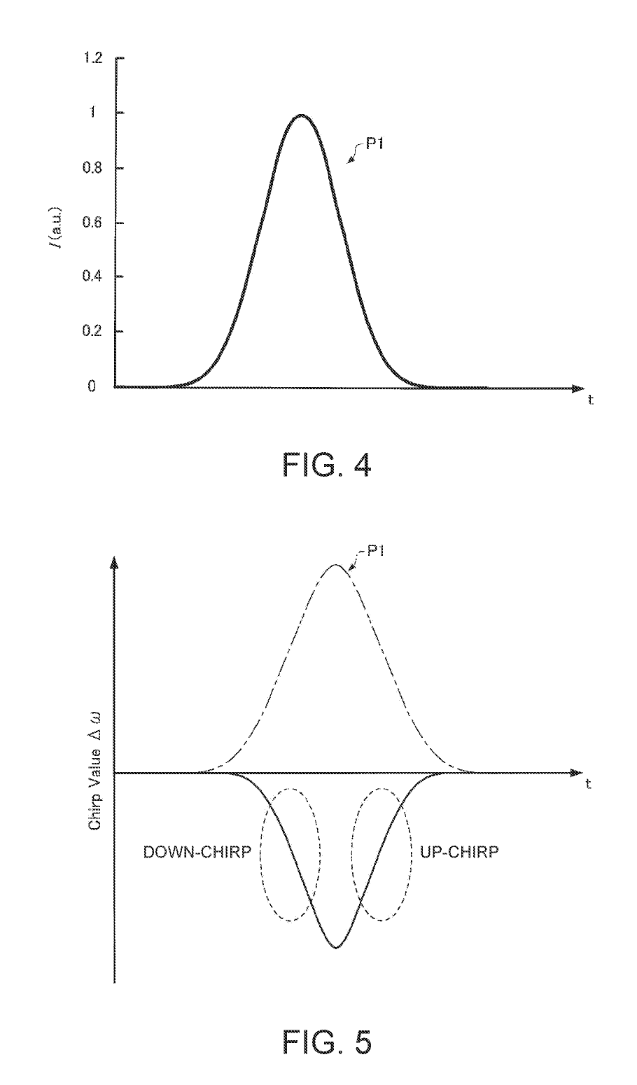

Next, operations of the short light pulse generation device 100 will be described. FIG. 4 is a graph illustrating an example of a light pulse P1 generated in the light pulse generation portion 10. The horizontal axis t of the graph shown in FIG. 4 is time, and the vertical axis I thereof is light intensity (the square of an electric field amplitude). FIG. 5 is a graph illustrating an example of the chirp characteristics of the frequency chirping portion 12. The horizontal axis t of the graph shown in FIG. 5 is time, and the vertical axis Δω thereof is the amount of chirp (the amount of frequency change). Meanwhile, in FIG. 5, the light pulse P1 is shown by a dashed-dotted line, and the amount of chirp Δω is shown by a solid line corresponding to the light pulse P1. FIG. 6 is a graph illustrating a mode of a light pulse in the group velocity dispersion portion 16. Meanwhile, the horizontal axis x of the graph shown in FIG. 6 is a distance, and the vertical axis E is an electric field. FIG. 7 is a graph illustrating an example of a light pulse P3 generated in the group velocity dispersion portion 16. The horizontal axis t of the graph shown in FIG. 7 is time, and the vertical axis I thereof is light intensity.

The light pulse generation portion 10 generates, for example, the light pulse P1 shown in FIG. 4. In the light pulse generation portion 10, the light pulse P1 is generated by the forward bias voltage of the pin diode being applied between the electrode 130 and the electrode 132. The light pulse P1 is a Gauss waveform in the shown example. The pulse width (full width at half maximum; FWHM) t of the light pulse P1 is 10 ps (picoseconds) in the shown example. The light pulse P1 is propagated through the optical waveguide 1, and is incident on the optical waveguide 2 of the frequency chirping portion 12.

The frequency chirping portion 12 has chirp characteristics proportional to light intensity. The following Expression (1) is an expression representing the effect of frequency chirp.

$$Δω = - \frac{{n}_{2} l {ω}_{0}}{2 c {τ}_{r}} {\vert E \vert}^{2} \qquad ( 1 )$$

Herein, Δω is the amount of chirp (the amount of frequency change), c is the speed of light, τᵣ is the response time of a non-linear refractive index effect, n₂ is a non-linear refractive index, l is a waveguide length, ω₀ is the center frequency of a light pulse, and E is the amplitude of an electric field.

The frequency chirping portion 12 gives frequency chirp shown in Expression (1) to the light pulse P1 propagated through the optical waveguide 2. Specifically, as shown in FIG. 5, with respect to the light pulse P1, the frequency chirping portion 12 decreases a frequency over time in the former part of the light pulse P1, and increases a frequency over time in the latter part of the light pulse P1. That is, the frequency chirping portion 12 down-chirps the former part of the light pulse P1, and up-chirps the latter part of the light pulse P1. Therefore, the light pulse P1 generated in the light pulse generation portion 10 passes through the frequency chirping portion 12, and thus is changed to a light pulse (hereinafter, referred to as a “light pulse P2”) in which the former part is down-chirped and the latter part is up-chirped. The chirped light pulse P2 (not shown) is incident on the optical waveguide 4 of the light branching portion 14.

The light branching portion 14 branches the chirped light pulse P2. Specifically, the light pulse P2 propagated through the optical waveguide 4 is branched into the light pulse P2 propagated through the optical waveguide 4a and the light pulse P2 propagated through the optical waveguide 4b at the branch point F. The light pulse P2 propagated through the optical waveguide 4a is incident on the optical waveguide 6a of the group velocity dispersion portion 16, and the light pulse P2 propagated through the optical waveguide 4b is incident on the optical waveguide 6b of the group velocity dispersion portion 16. Here, in the light branching portion 14, the length L₁ of the optical waveguide 4a and the length L₂ of the optical waveguide 4b are equal to each other. For this reason, the light path lengths of the light pulses P2 in two light paths before the light pulse is branched in the light branching portion 14 and then is incident on the group velocity dispersion portion 16 become equal to each other. Therefore, the light pulse P2 which is propagated through the optical waveguide 4a and is incident on the group velocity dispersion portion 16 and the light pulse P2 which is propagated through the optical waveguide 4b and is incident on the group velocity dispersion portion 16 are set to be in-phase in the incidence planes 17a and 17b of the group velocity dispersion portion 16.

The group velocity dispersion portion 16 produces a group velocity difference depending on a wavelength (frequency) with respect to the chirped light pulse P2 (group velocity dispersion), and performs pulse compression. In the group velocity dispersion portion 16, the light pulse P2 passes through a coupled waveguide constituted by the optical waveguides 6a and 6b, and thus a group velocity difference is produced in the light pulse P2. Here, in the group velocity dispersion portion 16, since the light pulses P2 incident on the optical waveguides 6a and 6b are in-phase, the mode of the light pulse P2 in the group velocity dispersion portion 16 is set to an even mode, as shown in FIG. 6. Thereby, the group velocity dispersion portion 16 can have positive group velocity dispersion characteristics.

As shown in FIG. 7, the group velocity dispersion portion 16 produces positive group velocity dispersion in the light pulse P2, and compresses the former part of the down-chirped light pulse P2. Thereby, the light pulse P3 is generated. In the shown example, the pulse width t of the light pulse P3 is 0.33 ps. The light pulse P3 is emitted from at least one of the end face of the optical waveguide 6a and the end face of the optical waveguide 6b which are provided on the lateral side 109b of the core layer 108.

### 1.4. Group Velocity Dispersion Characteristics of Group Velocity Dispersion Portion

Next, the group velocity dispersion characteristics of the group velocity dispersion portion 16 will be described.

An electric field E in a coupled waveguide constituted by a waveguide a and a waveguide b is represented by the following Expression (2).

E=A(z)E₁+B(z)E₂ (2)

Herein E₁ is an electric field when only the waveguide a is present, and E₂ is an electric field when only the waveguide b is present. In addition, A(z) is an electric field amplitude of the waveguide a, and B(z) is an electric field amplitude of the waveguide b.

Herein, A(z) and B(z) are represented by the following Expression (3).

$$\begin{matrix}[ \begin{matrix}A ( z ) \\ B ( z )\end{matrix} ] = {e}^{- j \overline{β} z} [ \begin{matrix}cos sz - j \frac{δ}{s} sin sz & - j \frac{{K}_{12}}{s} sin sz \\ - j \frac{{K}_{12}}{s} sin sz & cos sz + j \frac{δ}{s} sin sz\end{matrix} ] [ \begin{matrix}A ( 0 ) \\ B ( 0 )\end{matrix} ] \\ = \frac{1}{2 s} [ \begin{matrix}( s + δ ) A ( 0 ) + {K}_{12} B ( 0 ) \\ {K}_{12} A ( 0 ) + ( s - δ ) B ( 0 )\end{matrix} ] {e}^{- {jβ}_{+} z} + \\ \frac{1}{2 s} [ \begin{matrix}( s - δ ) A ( 0 ) - {K}_{12} B ( 0 ) \\ - {K}_{12} A ( 0 ) + ( s + δ ) B ( 0 )\end{matrix} ] {e}^{- {jβ}_{-} z}\end{matrix} \qquad ( 3 )$$

In addition, β̅, δ, s and β_{±} are as follows.

$$\overline{β} = \frac{{β}_{1} + {β}_{2}}{2} \\ δ = \frac{{β}_{1} - {β}_{2}}{2} \\ s = \sqrt{{δ}^{2} + {K}_{12}^{2}} \\ {β}_{\pm } = \overline{β} \pm s \qquad ( 4 )$$

However, A(0) is an amplitude of an electric field which is incident on the waveguide a, B(0) is an amplitude of an electric field which is incident on the waveguide b, β₁ is a propagation constant when only the waveguide a is present, β₂ is a propagation constant when only the waveguide b is present, K₁₂ is a coefficient of coupling (from the waveguide a to the waveguide b), β₊ is a propagation constant of an even mode, and β₋ is a propagation constant of an odd mode.

Here, in the coupled waveguide, the group velocity dispersion obtains a maximum value in a wavelength when β₁=β₂. Consequently, for example, when a short pulse having a wavelength of 850 nm is desired to be obtained, β₁, and β₂ are set so that the wavelength when β₁=β₂ is set to 850 nm. Therefore, when the relation of β₁=β₂ is established, each expression of (4) is represented as follows.

δ=0

s=K₁₂ β_{±}=±K₁₂

Therefore, Expression (3) is represented as in the following Expression (5).

$$[ \begin{matrix}A ( z ) \\ B ( z )\end{matrix} ] = \frac{( {A}_{0} + {B}_{0} )}{2} ( \begin{matrix}1 \\ 1\end{matrix} ) {e}^{- {jβ}_{+} z} + \frac{( {A}_{0} - {B}_{0} )}{2} ( \begin{matrix}1 \\ - 1\end{matrix} ) {e}^{- {jβ}_{-} x} \qquad ( 5 )$$

In Expression (5), A₀ is an amplitude of an electric field which is incident on the waveguide a, and the relation of A₀=A(0) is established. In addition, B₀ is an amplitude of an electric field which is incident on the waveguide b, and the relation of B₀=B(0) is established.

Here, when A₀ and B₀ have the same phase, that is, when the relation of A₀=B₀ is established, the second term of Expression (5) disappears, and only the first term thereof remains. The first term thereof is a term of an even mode, that is, a term for creating positive group velocity dispersion. Therefore, in the coupled waveguide, the incidence of light having the same phase produces positive group velocity dispersion.

On the other hand, when A₀ and B₀ have opposite phases, that is, when the relation of A₀=−B₀ is established, the first term of Expression (5) disappears, and only the second term thereof remains. The second term thereof is a term of an odd mode, that is, a term for creating negative group velocity dispersion. Therefore, in the coupled waveguide, the incidence of light having an opposite phase produces negative group velocity dispersion.

The short light pulse generation device 100 according to the embodiment has, for example, the following features.

The short light pulse generation device 100 includes the light pulse generation portion 10 that has a quantum well structure and generates a light pulse, the frequency chirping portion 12 that has a quantum well structure and chirps a frequency of the light pulse, the light branching portion 14 that branches the chirped light pulse, and the group velocity dispersion portion 16 that has a plurality of optical waveguides 6a and 6b, disposed at a mode coupling distance, on which each of a plurality of light pulses branched in the light branching portion 14 is incident, and produces a group velocity difference depending on a wavelength with respect to the plurality of branched light pulses. The light path lengths of the light pulses in a plurality of light paths before the light pulse is branched in the light branching portion 14 and then incident on the plurality of optical waveguides 6a and 6b of the group velocity dispersion portion 16 are equal to each other. Thereby, it is possible to emit a light pulse (short light pulse) having a pulse width of, for example, equal to or greater than 1 fs and equal to or less than 800 fs by compressing the light pulse generated in the light pulse generation portion 10 (reducing the pulse width thereof).

Further, since the light path lengths of the light pulses before the light pulse is branched in the light branching portion 14 and then incident on the group velocity dispersion portion 16 are equal to each other, the light pulses which are branched and incident on the group velocity dispersion portion 16 can be set to be in-phase. Thereby, the group velocity dispersion portion 16 can have positive group velocity dispersion characteristics. In this manner, in the short light pulse generation device 100, since the group velocity dispersion portion 16 can be controlled so as to have positive group velocity dispersion characteristics, it is possible to obtain a light pulse having a desired pulse width.

In the short light pulse generation device 100, the light branching portion 14 includes the optical waveguide 4 which is made of a semiconductor material and on which the chirped light pulse is incident, and the optical waveguide 4a and the optical waveguide 4b which are made of the same semiconductor material as that of the optical waveguide 4 and are branched from the optical waveguide 4. The length L₁ of the optical waveguide 4a and the length L₂ of the optical waveguide 4b are equal to each other. Therefore, the light pulses which are branched and incident on the group velocity dispersion portion 16 can be set to be in-phase.

According to the short light pulse generation device 100, the frequency chirping portion 12 has a quantum well structure, and thus it is possible to achieve a reduction in size of a device. Hereinafter, the reason will be described.

As shown in Expression (1) mentioned above, the amount of chirp Δω is proportional to a non-linear refractive index n₂. That is, as the non-linear refractive index becomes higher, the amount of chirp per unit length becomes larger. Here, the non-linear refractive index n₂ of a general quartz fiber (SiO₂) is approximately 10⁻²⁰ m²/W. On the other hand, the non-linear refractive index n₂ of the semiconductor material having a quantum well structure is approximately 10⁻¹⁰ to 10⁻⁸ m²/W. In this manner, the semiconductor material having a quantum well structure has the non-linear refractive index n₂ much higher than that of the quartz fiber. For this reason, the semiconductor material having a quantum well structure is used as the frequency chirping portion 12, thereby allowing the amount of chirp per unit length to be made larger than that in the case where the quartz fiber is used, and allowing the length of an optical waveguide for giving frequency chirp to be made shorter than that. Therefore, it is possible to reduce the size of the frequency chirping portion 12, and to achieve a reduction in size of a device.

In the short light pulse generation device 100, since the group velocity dispersion portion 16 includes two optical waveguides 6a and 6b disposed at a mode coupling distance, mode coupling allows a large group velocity difference to be produced in the light pulse. Therefore, it is possible to shorten the length of the optical waveguide for producing a group velocity difference, and to achieve a reduction in size of a device.

In the short light pulse generation device 100, since the group velocity dispersion portion 16 is made of a semiconductor material (semiconductor layers 104, 106, 108, 110, and 112), it is possible to easily form the coupled waveguides (optical waveguides 6a and 6b) as compared with, for example, the quartz fiber.

In the short light pulse generation device 100, the light pulse generation portion 10, the frequency chirping portion 12, the light branching portion 14, and the group velocity dispersion portion 16 are provided on the same substrate 102. Therefore, a semiconductor layer constituting the light pulse generation portion 10, a semiconductor layer constituting the frequency chirping portion 12, a semiconductor layer constituting the light branching portion 14, and a semiconductor layer constituting the group velocity dispersion portion 16 can be efficiently formed by the same process, using epitaxial growth or the like. Further, it is possible to facilitate an alignment between the light pulse generation portion 10 and the frequency chirping portion 12, an alignment between the frequency chirping portion 12 and the light branching portion 14, and an alignment between the light branching portion 14 and the group velocity dispersion portion 16.

In the short light pulse generation device 100, the core layer 108 constituting the optical waveguide 1 of the light pulse generation portion 10, the core layer 108 constituting the optical waveguide 2 of the frequency chirping portion 12, the core layer 108 constituting the optical waveguides 4, 4a, and 4b of the light branching portion 14, and the core layer 108 constituting the optical waveguides 6a and 6b of the group velocity dispersion portion 16 are provided on the same layer, and are continuous with each other. Thereby, it is possible to reduce a light loss between the light pulse generation portion 10 and the frequency chirping portion 12, a light loss between the frequency chirping portion 12 and the light branching portion 14, and a light loss between the light branching portion 14 and the group velocity dispersion portion 16. For example, when the core layer constituting the optical waveguide 1 of the light pulse generation portion 10 and the core layer constituting the optical waveguide 2 of the frequency chirping portion 12 are not continuous with each other, that is, when a space, an optical element or the like is present between these layers, a light loss may occur before the light pulse is emitted from the light pulse generation portion 10 and is incident on the frequency chirping portion 12. In addition, the same is true of a case where the core layer of the frequency chirping portion 12 and the core layer of the light branching portion 14 are not continuous with each other, and a case where the core layer of the light branching portion 14 and the core layer of the group velocity dispersion portion 16 are not continuous with each other.

In the short light pulse generation device 100, the light branching portion 14 includes a plurality of laminated semiconductor layers 104, 106, 108, 110, and 112, and a plurality of optical waveguides 4a and 4b are arranged in a direction perpendicular to the lamination direction of these semiconductor layers. Similarly, the group velocity dispersion portion 16 includes a plurality of laminated semiconductor layers 104, 106, 108, 110, and 112, and a plurality of optical waveguides 6a and 6b are arranged in a direction perpendicular to the lamination direction of these semiconductor layers. Therefore, for example, as compared with a case where the optical waveguides 4a and 4b and the optical waveguides 6a and 6b are arranged in the lamination direction, it is possible to reduce the number of laminated semiconductor layers constituting the light branching portion 14 or the group velocity dispersion portion 16. Therefore, it is possible to simplify manufacturing processes, and to lower manufacturing costs.

### 1.2. Method of Manufacturing Short Light Pulse Generation Device

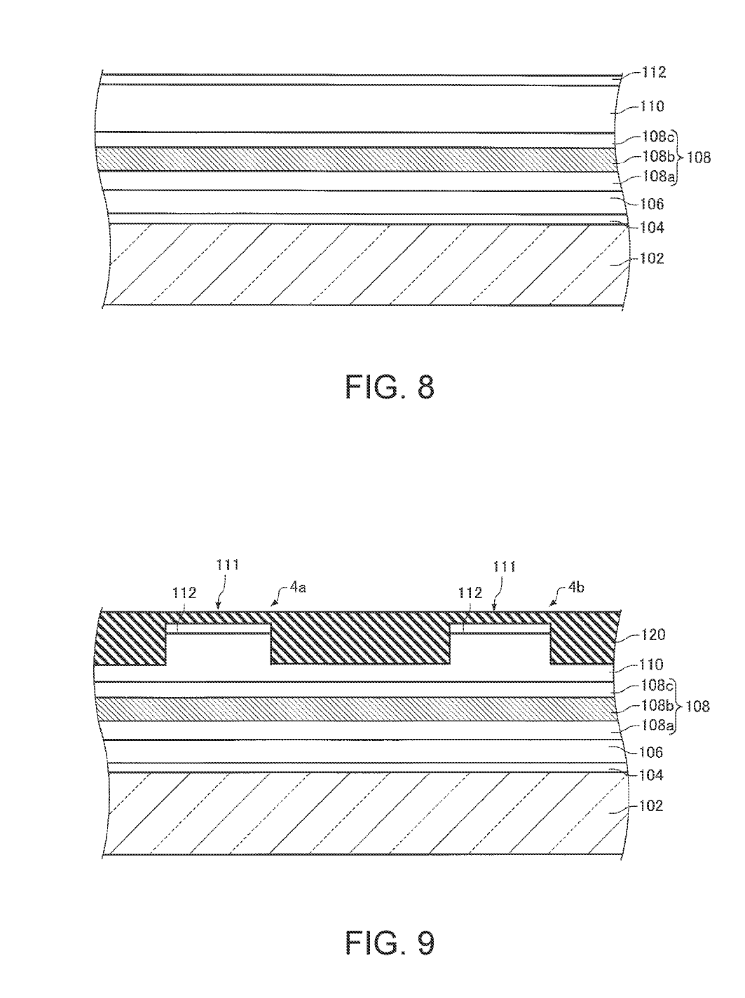

Next, a method of manufacturing the short light pulse generation device according to the embodiment will be described with reference to the accompanying drawings. FIGS. 8 and 9 are cross-sectional views schematically illustrating processes of manufacturing the short light pulse generation device 100 according to the embodiment.

As shown in FIG. 8, the buffer layer 104, the first cladding layer 106, the core layer 108, the second cladding layer 110, and the cap layer 112 are epitaxially grown on the substrate 102 in this order. As an epitaxial growth method, for example, an MOCVD (Metal Organic Chemical Vapor Deposition) method, an MBE (Molecular Beam Epitaxy) method or the like can be used. Meanwhile, when the core layer 108 is formed, the first guide layer 108a and the MQW layer 108b are first grown on the first cladding layer 106. Next, the second guide layer 108c is grown on the MQW layer 108b. Interference exposure and etching are then performed on the upper surface of the second guide layer 108c located above the first region 102a to form a corrugated surface (see FIG. 1). Thereafter, the second cladding layer 110 having a different refractive index is grown on the second guide layer 108c including the upper portion of the corrugated surface. Thereby, a periodic structure is formed in the second guide layer 108c. In this manner, the core layer 108 is formed.

As shown in FIG. 9, the cap layer 112 and the second cladding layer 110 are etched to form the columnar portion 111. Next, the insulating layer 120 is formed laterally of the columnar portion 111 and on the columnar portion 111. The insulating layer 120 is not formed on the columnar portion 111 located above the first region 102a. The insulating layer 120 is formed by, for example, a CVD method, an application method or the like.

As shown in FIG. 1, the electrode 132 is formed on the columnar portion 111 (cap layer 112) located above the first region 102a. The electrode is formed through film formation on the cap layer 112 by a vacuum vapor deposition method. Next, the electrode 130 is formed below the lower surface of the substrate 102. The electrode 130 is formed by, for example, a vacuum vapor deposition method. Meanwhile, the order of forming the electrode 130 and the electrode 132 is not particularly limited.

The short light pulse generation device 100 can be manufactured by the above processes.

According to the method of manufacturing the short light pulse generation device of the embodiment, it is possible to obtain the short light pulse generation device 100 capable of obtaining a light pulse having a desired pulse width.

### 1.5. Modification Examples of Short Light Pulse Generation Device

Next, short light pulse generation devices according to modification examples of the embodiment will be described with reference to the accompanying drawings. In the short light pulse generation devices according to the modification examples of the embodiment described below, members having the same functions as those of the configuration members of the above-mentioned short light pulse generation device 100 are assigned the same reference numerals and signs, and thus the detailed description thereof will be omitted.

### 1. First Modification Example

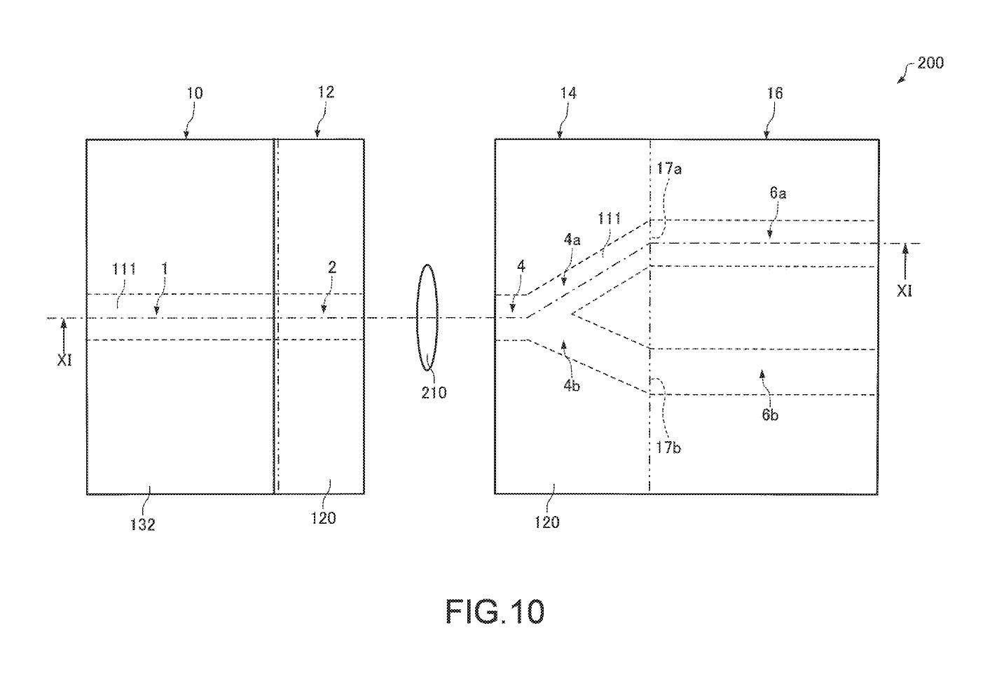

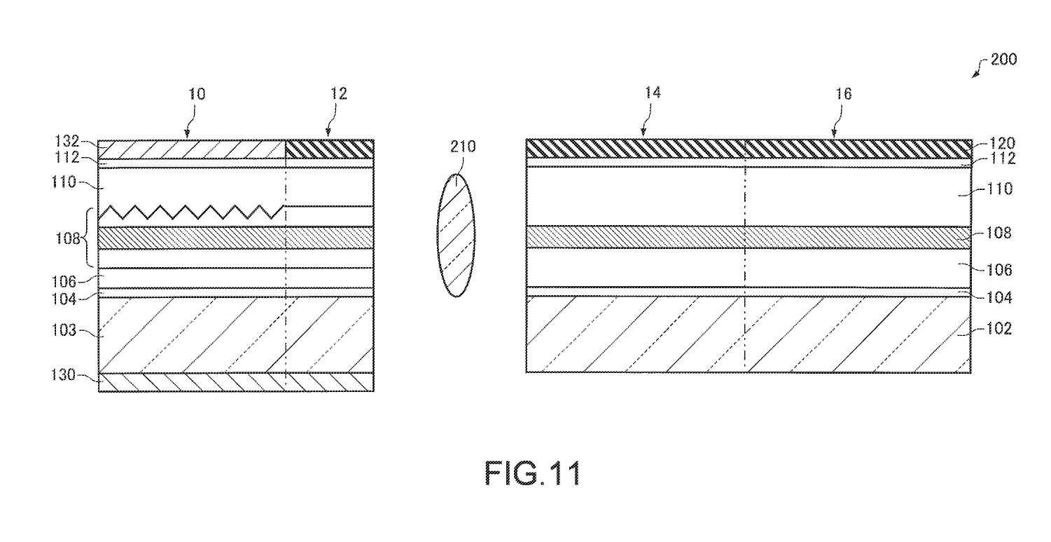

First, a first modification example will be described. FIG. 10 is a plan view schematically illustrating a short light pulse generation device 200 according to the first modification example. FIG. 11 is a cross-sectional view schematically illustrating the short light pulse generation device 200 according to the first modification example. Meanwhile, FIG. 11 is a cross-sectional view taken along line XI-XI of FIG. 10.

In the above-mentioned short light pulse generation device 100, as shown in FIGS. 1 and 2, the light pulse generation portion 10, the frequency chirping portion 12, the light branching portion 14, and the group velocity dispersion portion 16 are integrally provided.

On the other hand, in the short light pulse generation device 200, as shown in FIGS. 10 and 11, the light pulse generation portion 10 and the frequency chirping portion 12 are integrally provided, and the light branching portion 14 and the group velocity dispersion portion 16 are integrally provided. That is, in the short light pulse generation device 200, the light pulse generation portion 10 and the frequency chirping portion 12 are provided on the same substrate 103, and the light branching portion 14 and the group velocity dispersion portion 16 are provided on the same substrate 102.

The light pulse generation portion 10 and the frequency chirping portion 12 are provided on the substrate 103 different from the substrate 102 provided with the light branching portion 14 and the group velocity dispersion portion 16. The material of the substrate 103 is the same as that of, for example, the substrate 102.

The core layer 108 of the light branching portion 14 and the core layer 108 of the group velocity dispersion portion 16 may not have a quantum well structure. The core layer 108 is, for example, a monolayer AlGaAs layer.

An optical element 210 is disposed between the frequency chirping portion 12 and the light branching portion 14. The optical element 210 is a lens for making a light pulse emitted from the frequency chirping portion 12 incident on the optical waveguide 4 of the light branching portion 14. Meanwhile, the light pulse emitted from the light branching portion 14 may be made directly incident on the optical waveguide 4 of the light branching portion 14 without providing the optical element 210.

Meanwhile, the layer structure (band structure) of the semiconductor layers 104, 106, 108, 110, and 112 constituting the group velocity dispersion portion 16 is not particularly limited. For example, these semiconductor layers 104 to 112 may be all formed of n-type (or p-type) semiconductor layers.

According to the short light pulse generation device 200, since the light pulse generation portion 10 and the frequency chirping portion 12 are provided on the same substrate 103, the semiconductor layer constituting the light pulse generation portion 10 and the semiconductor layer constituting the frequency chirping portion 12 can be efficiently formed by the same process using epitaxial growth or the like. Further, it is possible to facilitate an alignment between the light pulse generation portion 10 and the light branching portion 14. Further, it is possible to reduce a light loss between the light pulse generation portion 10 and the frequency chirping portion 12.

Further, according to the short light pulse generation device 200, since the light branching portion 14 and the group velocity dispersion portion 16 are provided on the same substrate 102, the semiconductor layer constituting the light branching portion 14 and the semiconductor layer constituting the group velocity dispersion portion 16 can be efficiently formed by the same process using epitaxial growth or the like. Further, it is possible to facilitate an alignment between the light branching portion 14 and the group velocity dispersion portion 16. Further, it is possible to reduce a light loss between the light branching portion 14 and the group velocity dispersion portion 16.

### 2. Second Modification Example

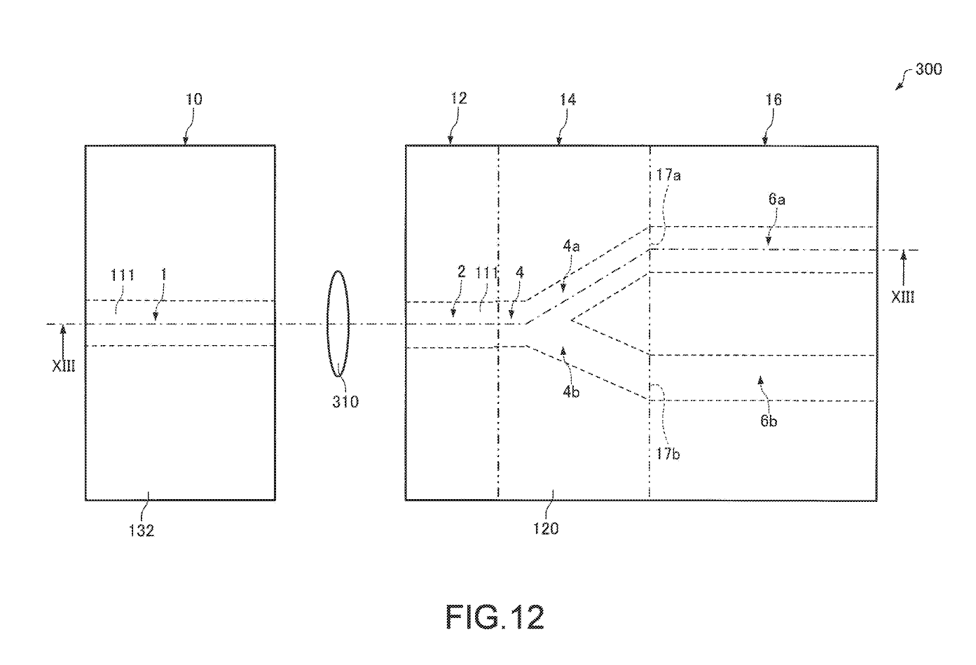

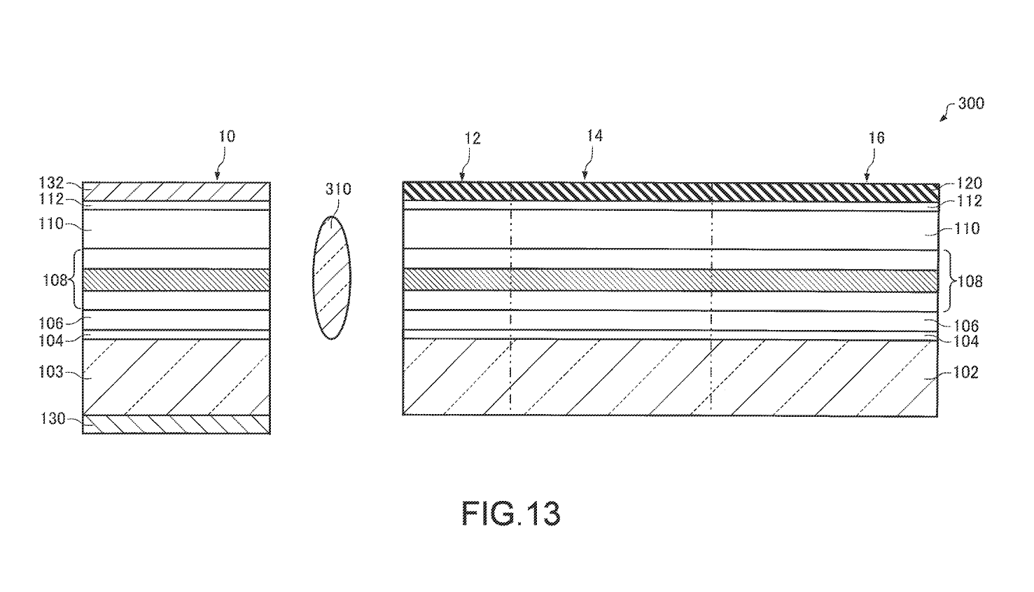

Next, a second modification example will be described. FIG. 12 is a plan view schematically illustrating the short light pulse generation device 300 according to a second modification example. FIG. 13 is a cross-sectional view schematically illustrating the short light pulse generation device 300 according to the second modification example. Meanwhile, FIG. 13 is a cross-sectional view taken along line XIII-XIII of FIG. 12.

In the above-mentioned short light pulse generation device 100, as shown in FIGS. 1 and 2, the light pulse generation portion 10, the frequency chirping portion 12, the light branching portion 14, and the group velocity dispersion portion 16 are integrally provided.

On the other hand, in the short light pulse generation device 300, as shown in FIGS. 12 and 13, the frequency chirping portion 12, the light branching portion 14, and the group velocity dispersion portion 16 are integrally provided. That is, in the short light pulse generation device 300, the frequency chirping portion 12, the light branching portion 14, and the group velocity dispersion portion 16 are provided on the same substrate 102.

Insofar as a light pulse can be emitted, the configuration of the light pulse generation portion 10 is not particularly limited. In the shown example, the light pulse generation portion 10 is a Fabry-Perot-type semiconductor laser. An optical element 310 is disposed between the light pulse generation portion 10 and the frequency chirping portion 12. The optical element 310 is a lens for making a light pulse emitted from the light pulse generation portion 10 incident on the frequency chirping portion 12. Meanwhile, the light pulse emitted from the light pulse generation portion 10 may be made directly incident on the frequency chirping portion 12 without providing the optical element 310.

According to the short light pulse generation device 300, since the frequency chirping portion 12, the light branching portion 14, and the group velocity dispersion portion 16 are provided on the same substrate 102, the semiconductor layer constituting the frequency chirping portion 12, the semiconductor layer constituting the light branching portion 14, and the semiconductor layer constituting the group velocity dispersion portion 16 can be efficiently formed by the same process using epitaxial growth or the like. Further, it is possible to facilitate an alignment between the frequency chirping portion 12 and the light branching portion 14 and an alignment between the light branching portion 14 and the group velocity dispersion portion 16. Further, it is possible to reduce a light loss between the frequency chirping portion 12 and the light branching portion 14 and a light loss between the light branching portion 14 and the group velocity dispersion portion 16.

### 3. Third Modification Example

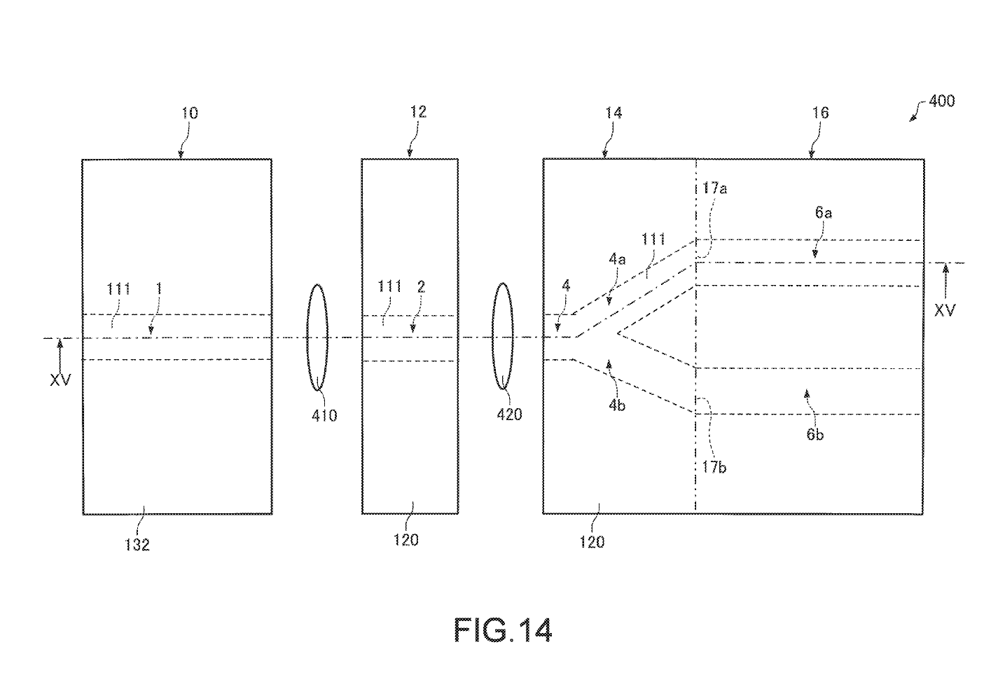

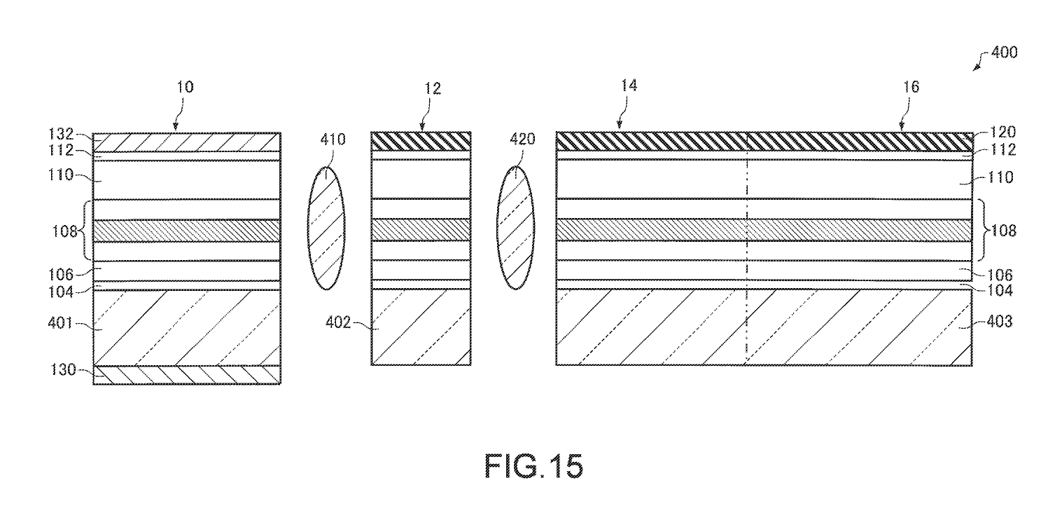

Next, a third modification example will be described. FIG. 14 is a plan view schematically illustrating a short light pulse generation device 400 according to the third modification example. FIG. 15 is a cross-sectional view schematically illustrating the short light pulse generation device 400 according to the third modification example. Meanwhile, FIG. 15 is a cross-sectional view taken along line XV-XV of FIG. 14.

In the above-mentioned short light pulse generation device 100, as shown in FIGS. 1 and 2, the light pulse generation portion 10, the frequency chirping portion 12, and the group velocity dispersion portion 16 are integrally provided.

On the other hand, in the short light pulse generation device 400, as shown in FIGS. 14 and 15, the light pulse generation portion 10, the frequency chirping portion 12, the light branching portion 14 and the group velocity dispersion portion 16 are separately provided. That is, in the short light pulse generation device 400, the light pulse generation portion 10 is provided on a substrate 401, the frequency chirping portion 12 is provided on a substrate 402, and the light branching portion 14 and the group velocity dispersion portion 16 are provided on a substrate 403. As the substrates 401, 402, and 403, for example, an n-type GaAs substrate or the like can be used.

An optical element 410 is disposed between the light pulse generation portion 10 and the frequency chirping portion 12. The optical element 410 is a lens for making a light pulse emitted from the light pulse generation portion 10 incident on the frequency chirping portion 12. In addition, an optical element 420 is disposed between the frequency chirping portion 12 and the light branching portion 14. The optical element 420 is a lens for making a light pulse emitted from the frequency chirping portion 12 incident on the light branching portion 14. Meanwhile, the light pulse emitted from the light pulse generation portion 10 may be made directly incident on the frequency chirping portion 12 without providing the optical element 410. In addition, the light pulse emitted from the frequency chirping portion 12 may be made directly incident on the light branching portion 14 without providing the optical element 420.

### 4. Fourth Modification Example

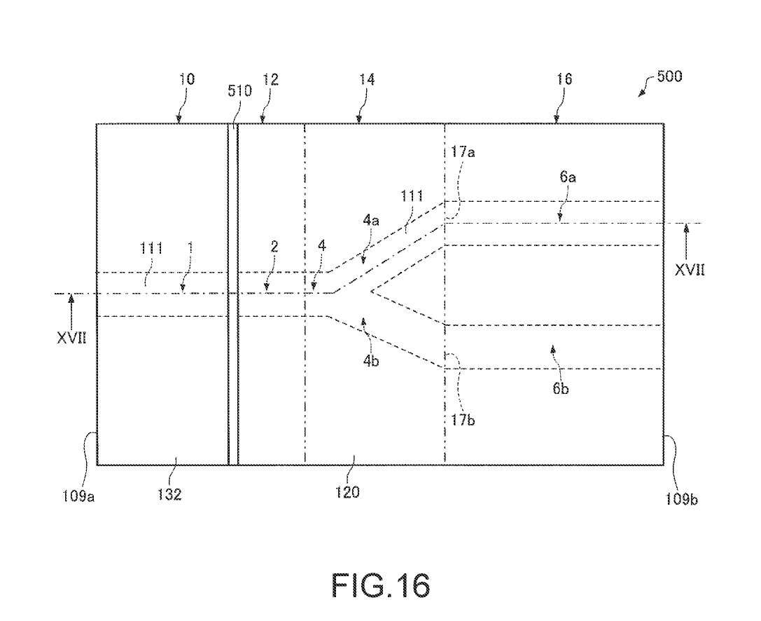

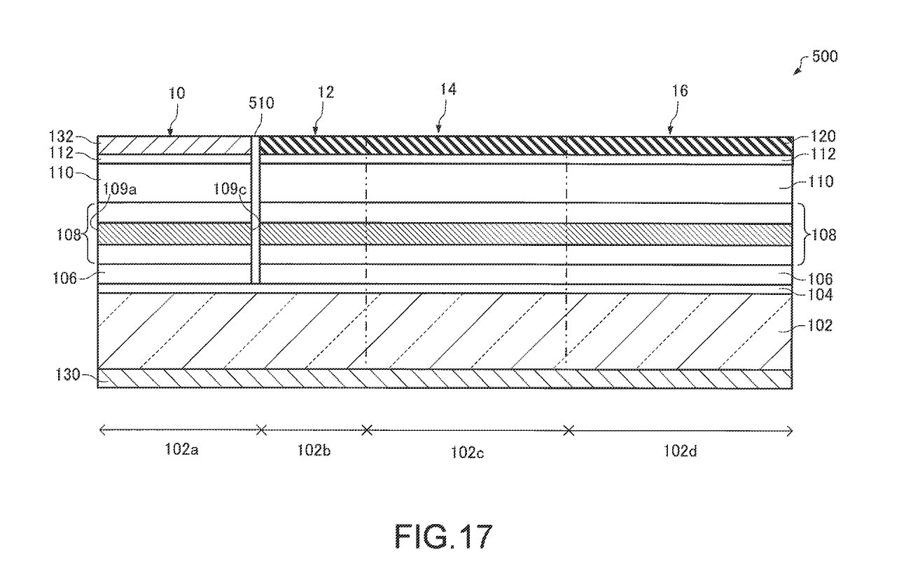

Next, a fourth modification example will be described. FIG. 16 is a plan view schematically illustrating a short light pulse generation device 500 according to the fourth modification example. FIG. 17 is a cross-sectional view schematically illustrating the short light pulse generation device 500 according to the fourth modification example. Meanwhile, FIG. 17 is a cross-sectional view taken along line XVII-XVII of FIG. 16.

In the above-mentioned short light pulse generation device 100, as shown in FIG. 1, the light pulse generation portion 10 is a DFB laser.

On the other hand, in the short light pulse generation device 500, as shown in FIG. 17, the light pulse generation portion 10 is a Fabry-Perot-type semiconductor laser.

In the short light pulse generation device 500, a groove portion 510 is provided at a boundary between the first region 102a and the second region 102b when seen in plan view (when seen from the lamination direction of the semiconductor layers 104 to 112). The groove portion 510 is provided so as to pass through the cap layer 112, the second cladding layer 110, the core layer 108, and the first cladding layer 106. The groove portion 510 is provided, and thus an end face 109c is provided in the core layer 108. In the light pulse generation portion 10, the lateral side 109a and the end face 109c function as reflective surfaces, and constitute a Fabry-Perot resonator. A light pulse emitted from the end face 109c of the light pulse generation portion 10 passes through the groove portion 510, and is incident on the frequency chirping portion 12.

### 5. Fifth Modification Example

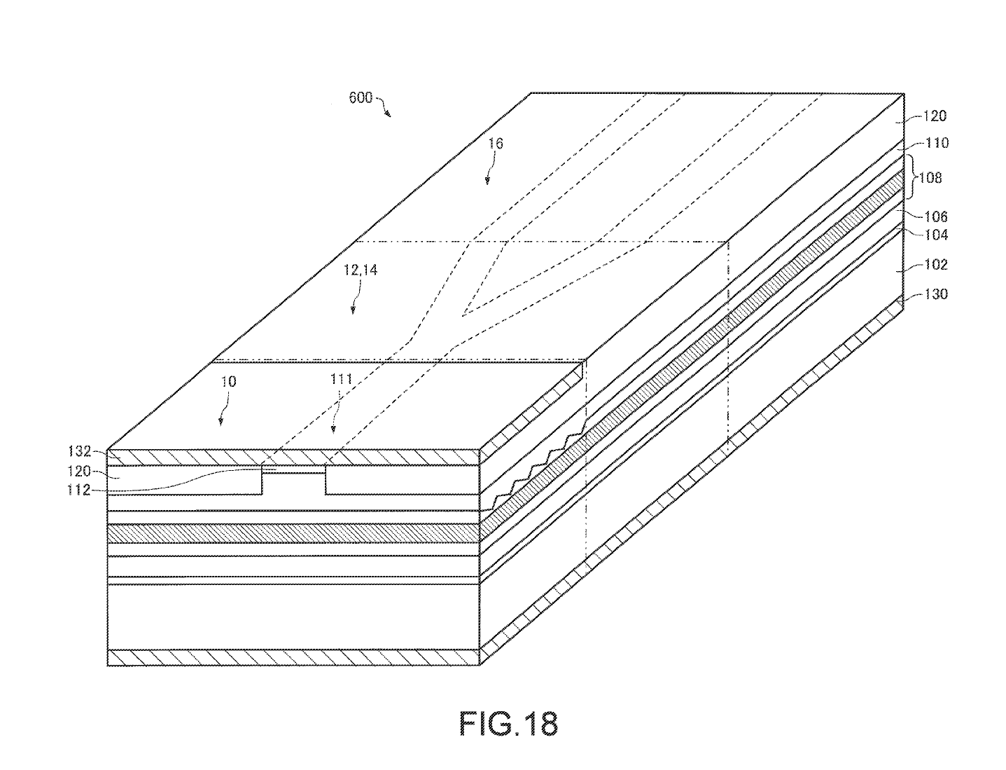

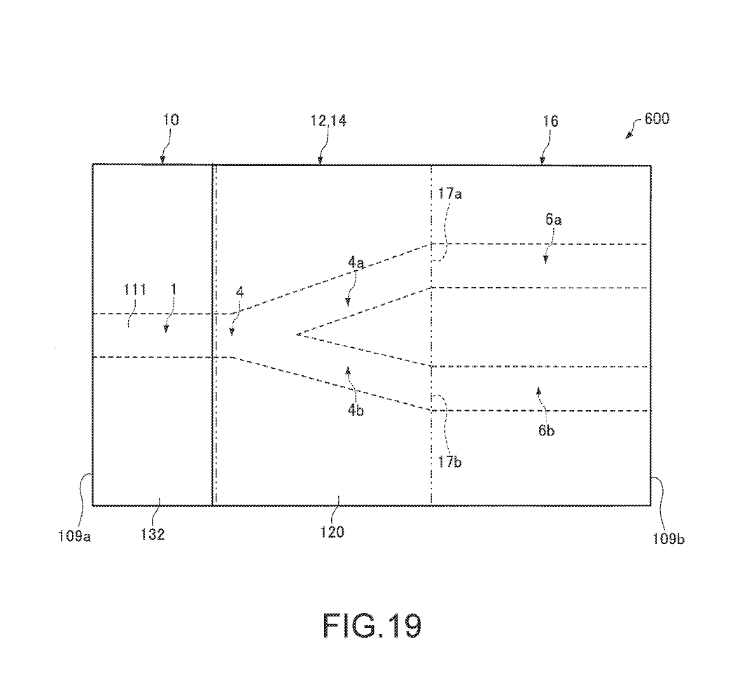

Next, a fifth modification example will be described. FIG. 18 is a perspective view schematically illustrating a short light pulse generation device 600 according to the fifth modification example. FIG. 19 is a plan view schematically illustrating the short light pulse generation device 600 according to the fifth modification example.

In the above-mentioned short light pulse generation device 100, as shown in FIGS. 1 and 2, the frequency of the light pulse is chirped in the frequency chirping portion 12, and the light pulse chirped in the light branching portion 14 is branched.

On the other hand, in the short light pulse generation device 600, as shown in FIGS. 18 and 19, the frequency chirping portion 12 and the light branching portion 14 are formed integrally with each other, and after the light pulse is branched, the frequency of the light pulse is chirped.

In the short light pulse generation device 600, the light pulse generated in the light pulse generation portion 10 is propagated through the optical waveguide 1, incident on the optical waveguide 4, and propagated through the optical waveguide 4. The light pulse propagated through the optical waveguide 4 is branched and propagated through the optical waveguides 4a and 4b. The light pulses propagated through the optical waveguides 4a and 4b are chirped while propagated through the optical waveguides 4a and 4b. The chirped light pulses are then incident on the optical waveguides 6a and 6b, produce a group velocity difference by passing through a coupled waveguide constituted by the optical waveguides 6a and 6b, and are compressed.

According to the short light pulse generation device 600, it is possible to exhibit the same operations and effects as those of the short light pulse generation device 100.

### 2. Second Embodiment

### 2.1. Configuration of Short Light Pulse Generation Device

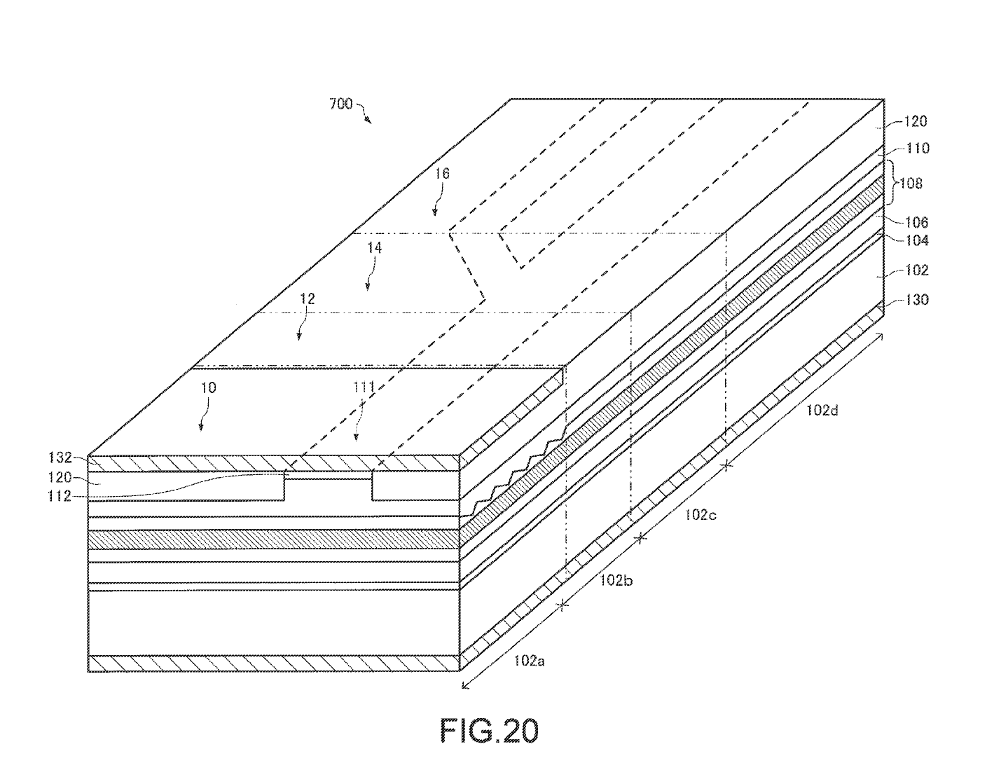

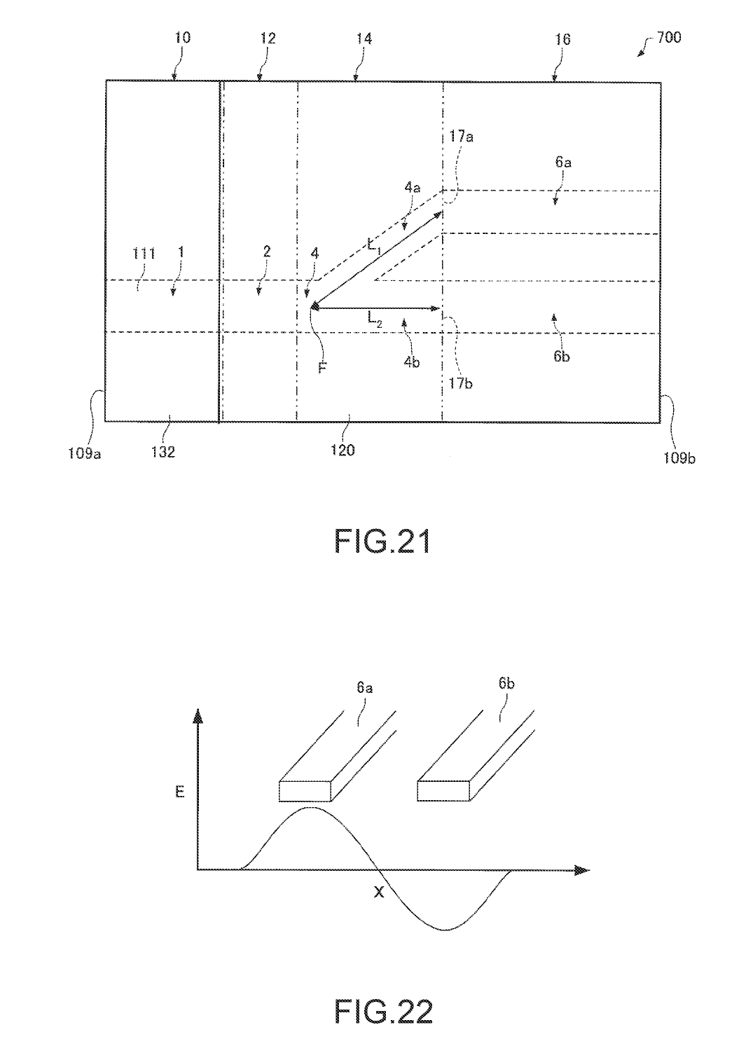

Next, a short light pulse generation device 700 according to a second embodiment will be described with reference to the accompanying drawings. FIG. 20 is a perspective view schematically illustrating the short light pulse generation device 700 according to the embodiment. FIG. 21 is a plan view schematically illustrating the short light pulse generation device 700 according to the embodiment. In the short light pulse generation device 700 according to the embodiment described below, members having the same functions as the configuration members of the above-mentioned short light pulse generation device 100 are assigned the same reference numerals and signs, and thus the detailed description thereof will be omitted.

In the above-mentioned short light pulse generation device 100, as shown in FIGS. 1 and 2, since the light path lengths of the light pulses before the light pulse is branched in the light branching portion 14 and then incident on the group velocity dispersion portion 16 are equal to each other, the light pulses incident on the group velocity dispersion portion 16 are set to be in-phase.

On the other hand, in the short light pulse generation device 700, as shown in FIGS. 20 and 21, the light branching portion 14 produces a light path difference in a plurality of branched light pulses which are set to have opposite phases to each other and are incident on the group velocity dispersion portion 16. That is, in the short light pulse generation device 700, the light pulses incident on the group velocity dispersion portion 16 are set to have opposite phases to each other. The term “opposite phase” as used herein refers to the phase difference between two light beams being 180 degrees.

The light branching portion 14 produces alight path difference in the plurality of branched light pulses which are set to have opposite phases to each other and are incident on the group velocity dispersion portion 16, and thus the light pulse which is propagated through the optical waveguide 4a and incident on the optical waveguide 6a and the light pulse which is propagated through the optical waveguide 4b and incident on the optical waveguide 6b are set to have opposite phases to each other. Therefore, the mode of the light pulse in the group velocity dispersion portion 16 is set to an odd mode. Thereby, the group velocity dispersion portion 16 can have negative group velocity dispersion characteristics. That is, the group velocity dispersion portion 16 can be used as an anomalous dispersion medium (see “1.4. Group Velocity Dispersion Characteristics of Group Velocity Dispersion Portion”). Meanwhile, the term “odd mode” as used herein refers to a mode having an electric field distribution with an opposite-phase belly (peak) in two optical waveguides (see FIG. 22). That is, in the odd mode, the light pulses are propagated with electric fields having reverse signs to each other, in the two optical waveguides 6a and 6b of the group velocity dispersion portion 16. In addition, the term “anomalous dispersion” as used herein refers to a phenomenon in which a refractive index increases as a wavelength gets longer.

The length L₁ of the optical waveguide 4a and the length L₂ of the optical waveguide 4b are different from each other. The optical waveguide 4a and the optical waveguide 4b are made of the same semiconductor material, and thus have the same refractive index. For this reason, a difference |L₁−L₂| between the length L₁ of the optical waveguide 4a and the length L₂ of the optical waveguide 4b allows a light path difference to be produced in the light pulse propagated through the optical waveguide 4a and the light pulse propagated through the optical waveguide 4b. Meanwhile, the width of the optical waveguide 4a and the width of the optical waveguide 4b have different sizes in the shown example. Meanwhile, the width of the optical waveguide 4a and the width of the optical waveguide 4b may have the same size.

Here, the difference |L₁−L₂| between the length L₁ of the optical waveguide 4a and the length L₂ of the optical waveguide 4b will be specifically described.

The phase of the light pulse (electromagnetic wave) which is propagated through the optical waveguide 4a and incident on the optical waveguide 6a is represented as follows.

e^{j(ωt-βL}^{₁}⁾

Herein, β is a propagation constant, t is a time, and ω is an angular frequency of light propagated through the optical waveguides 4a and 6a. Meanwhile, the propagation constant β is represented as follows.

$$β = {n}_{e} \frac{2 π}{{λ}_{o}}$$

Herein, nₑ is an equivalent refractive index, and λ₀ is a wavelength of light propagated through the optical waveguides 4a and 6a.

In addition, the phase of the light pulse (electromagnetic wave) which is propagated through the optical waveguide 4b and incident on the optical waveguide 6b is represented as follows.

e^{j(ωt-βL}^{₂}⁾

In order to set the phase of the light pulse which is propagated through the optical waveguide 4a and incident on the optical waveguide 6a and the phase of the light pulse which is propagated through the optical waveguide 4b and incident on the optical waveguide 6b to opposite phases, the phase of the light pulse which is incident on the optical waveguide 6a has only to be advanced by m×π (m is odd number) with respect to the phase of the light pulse which is incident on the optical waveguide 6b, and thus the following relational expression is established.

$$ω t - β {L}_{1} = ω t - β {L}_{2} - m π \\ {L}_{1} - {L}_{2} = m \frac{π}{β} = m \frac{{λ}_{0}}{2 {n}_{e}} \qquad ( 6 )$$

In this manner, the optical waveguide 4a and the optical waveguide 4b satisfy the relation of Expression (6), and thus the light branching portion 14 can produce a light path difference in the branched light pulses which are set to have opposite phases to each other and are incident on the group velocity dispersion portion 16.

For example, when the wavelength of the light pulse is set to 850 nm and the equivalent refractive index nₑ of the optical waveguides 4a and 4b is set to nₑ=3.4, the difference |L₁−L₂| in the length between the optical waveguide 4a and the optical waveguide 4b is as follows.

L₁−L₂=m×125 (nm)

The value of m can be appropriately set, for example, in consideration of the distance between the optical waveguides 6a and 6b.

Since the light pulses incident from the optical waveguides 4a and 4b have opposite phases to each other, the group velocity dispersion portion 16 has negative group velocity dispersion characteristics. Therefore, in the group velocity dispersion portion 16, negative group velocity dispersion is produced in the up-chirped light pulse, thereby allowing a pulse width to be reduced (pulse compression). That is, the group velocity dispersion portion 16 is an anomalous dispersion medium. The term “anomalous dispersion” as used herein refers to a phenomenon in which the group velocity becomes slower as the wavelength gets longer. Meanwhile, the width of the optical waveguide 6a and the width of the optical waveguide 6b have different sizes in the shown example. Meanwhile, the width of the optical waveguide 6a and the width of the optical waveguide 6b may have the same size.

The structure and the manufacturing method of the short light pulse generation device 700 are the same as those of the short light pulse generation device 100, and thus the description thereof will be omitted.

### 2.2. Operations of Short Light Pulse Generation Device

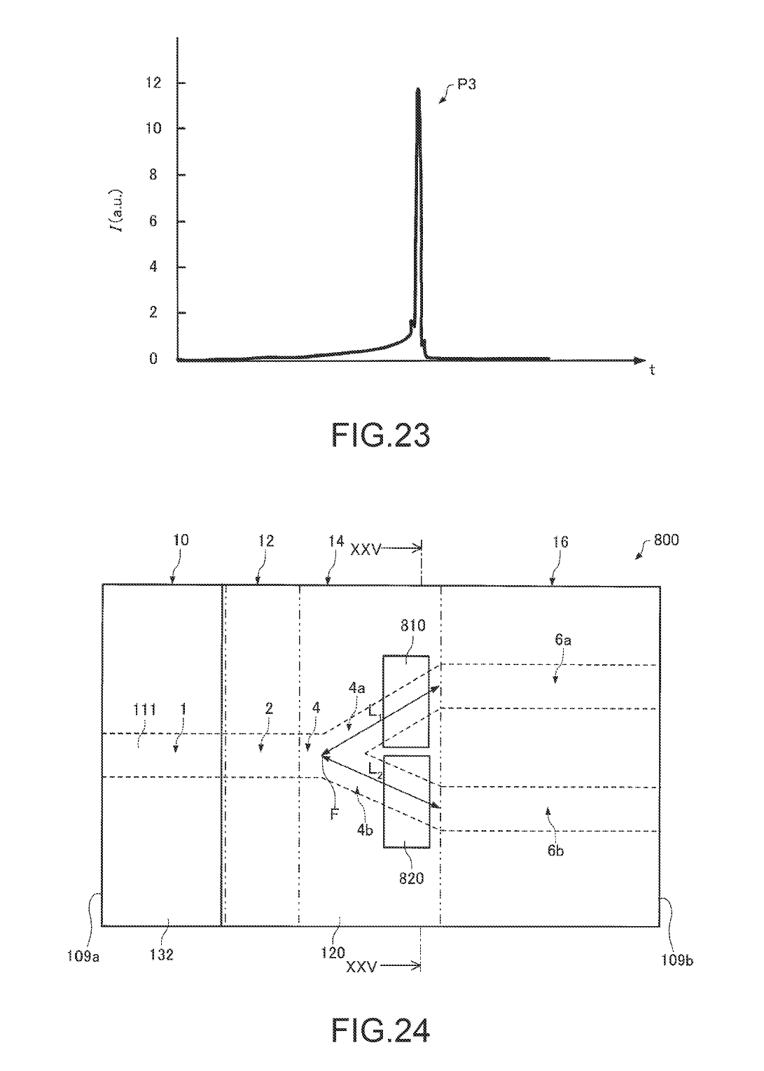

Next, operations of the short light pulse generation device 700 will be described. FIG. 22 is a diagram illustrating a mode of the light pulse in the group velocity dispersion portion 16. Meanwhile, the horizontal axis x of the graph shown in FIG. 22 is a distance, and the vertical axis E is an electric field. FIG. 23 is a graph illustrating an example of the light pulse P3 generated in the group velocity dispersion portion 16. The horizontal axis t of the graph shown in FIG. 23 is a time, and the vertical axis I is a light intensity.

The light pulse generation portion 10 generates, for example, the light pulse P1 shown in FIG. 4. The light pulse P1 is propagated through the optical waveguide 1, and is incident on the optical waveguide 2 of the frequency chirping portion 12.

As shown in FIG. 5, the frequency chirping portion 12 down-chirps the former part of the light pulse P1 and up-chirps the latter part of the light pulse P1, with respect to the light pulse P1 propagated through the optical waveguide 2. Therefore, the light pulse P1 generated in the light pulse generation portion 10 passes through the frequency chirping portion 12, and thus is changed to the light pulse P2 of which the former part is down-chirped and of which the latter part is up-chirped. The light pulse P2 (not shown) to which chirp is given is incident on the optical waveguide 4 of the light branching portion 14.

The light branching portion 14 branches the chirped light pulse P2. Here, in the light branching portion 14, a light path difference is produced in a plurality of branched light pulses which are set to have opposite phases to each other and are incident on the group velocity dispersion portion 16. Therefore, the light pulse P2 which is propagated through the optical waveguide 4a and is incident on the optical waveguide 6a and the light pulse P2 which is propagated through the optical waveguide 4b and is incident on the optical waveguide 6b are set to have opposite phases.

The group velocity dispersion portion 16 produces a group velocity difference depending on a wavelength (frequency) with respect to the light pulse P2 to which frequency chirp is given (group velocity dispersion), and performs pulse compression. In the group velocity dispersion portion 16, the light pulse P2 passes through a coupled waveguide constituted by the optical waveguides 6a and 6b, and thus a group velocity difference is produced in the light pulse P2. Here, in the group velocity dispersion portion 16, since the light pulses P2 incident on the optical waveguides 6a and 6b have opposite phases, the mode of the light pulse P2 in the group velocity dispersion portion 16 is set to an odd mode as shown in FIG. 22. Thereby, a group velocity dispersion portion 16 can have negative group velocity dispersion characteristics.

Since the group velocity dispersion portion 16 has negative group velocity dispersion characteristics, negative group velocity dispersion is produced in the light pulse P2 as shown in FIG. 23, and the latter part of the up-chirped light pulse P2 is compressed. Thereby, the light pulse P2 is compressed, and the light pulse P3 is generated.

The short light pulse generation device 700 according to the second embodiment has, for example, the following features.

According to the short light pulse generation device 700, since the light branching portion 14 can produce a light path difference in a plurality of branched light pulses which are set to have opposite phases to each other and are incident on the group velocity dispersion portion 16, the light pulse incident on the group velocity dispersion portion 16 can be set to have an opposite phase. Thereby, the group velocity dispersion portion 16 can have negative group velocity dispersion characteristics. In this manner, according to the short light pulse generation device 700, since the group velocity dispersion portion 16 can be controlled so as to have negative group velocity dispersion characteristics, it is possible to obtain a light pulse having a desired pulse width.

In the short light pulse generation device 700, the light branching portion 14 includes the optical waveguide 4 on which the chirped light pulse is incident and which is made of a semiconductor material, and the optical waveguide 4a and the optical waveguide 4b which are branched from the optical waveguide 4, and a light path difference between the light pulse propagated through the optical waveguide 4a and the light pulse propagated through the optical waveguide 4b is produced by a difference between the length L₁ of the optical waveguide 4a and the length L₂ of the optical waveguide 4b. Thereby, the light pulse incident on the group velocity dispersion portion 16 can be set to have an opposite phase.

### 2.3. Modification Example of Short Light Pulse Generation Device

Next, a short light pulse generation device according to a modification example of the embodiment will be described with reference to the accompanying drawings. In the short light pulse generation device according to the modification example of the embodiment described below, members having the same functions as the configuration members of the above-mentioned short light pulse generation device 700 are assigned the same reference numerals and signs, and thus the detailed description thereof will be omitted.

### 1. First Modification Example

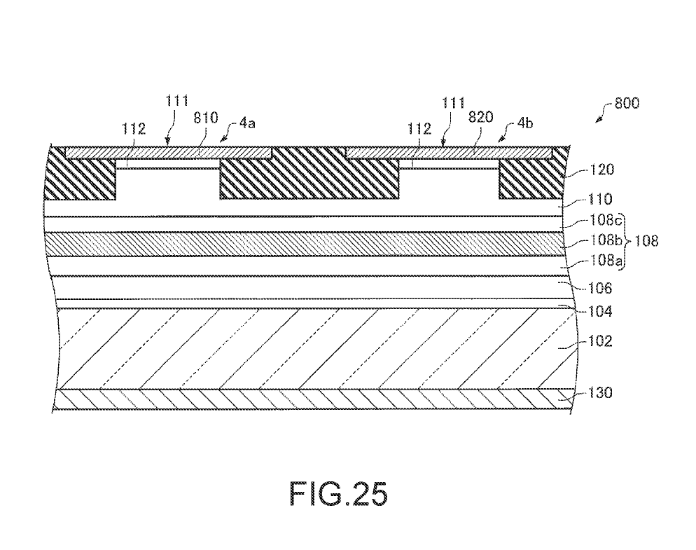

First, a first modification example will be described. FIG. 24 is a plan view schematically illustrating a short light pulse generation device 800 according to the first modification example. FIG. 25 is a cross-sectional view schematically illustrating the short light pulse generation device 800 according to the first modification example. Meanwhile, FIG. 25 is a cross-sectional view taken along line XXV-XXV of FIG. 24.

In the above-mentioned short light pulse generation device 700, as shown in FIG. 21, a difference |L₁−L₂| between the length L₁ of the optical waveguide 4a and the length L₂ of the optical waveguide 4b produces a light path difference in the branched light pulses which are set to have opposite phases to each other and are incident on the group velocity dispersion portion 16.

On the other hand, in the short light pulse generation device 800, as shown in FIGS. 24 and 25, a difference between the refractive index of the optical waveguide 4a and the refractive index of the optical waveguide 4b produces a light path difference by which the light pulse incident on the group velocity dispersion portion 16 is set to have an opposite phase.

Specifically, the short light pulse generation device 800 is configured to include a first electrode 810 that applies a voltage to the optical waveguide 4a of the light branching portion 14 and a second electrode 820 that applies a voltage to the optical waveguide 4b.

The first electrode 810 is provided on the upper surface of the cap layer 112 constituting the optical waveguide 4a. A voltage can be applied to the optical waveguide 4a by the first electrode 810 and the electrode 130.

The second electrode 820 is provided on the upper surface of the cap layer 112 constituting the optical waveguide 4b. A voltage can be applied to the optical waveguide 4b by the second electrode 820 and the electrode 130.

As the electrodes 810 and 820, for example, a layer or the like having a Cr layer, an AuZn layer, and an Au layer laminated in this order from the cap layer 112 side can be used.

Here, the first electrode 810 applies a voltage to a semiconductor layer constituting the optical waveguide 4a, and thus the refractive index of the optical waveguide 4a is changed by a non-linear optical effect. Similarly, the second electrode 820 applies a voltage to a semiconductor layer constituting the optical waveguide 4b, and thus the refractive index of the optical waveguide 4b is changed by a non-linear optical effect. Therefore, a voltage is applied to the optical waveguides 4a and 4b, thereby allowing the refractive index of the optical waveguide 4a and the refractive index of the optical waveguide 4b to be set to different refractive indexes. Thereby, a light path difference can be produced in the branched light pulses which are set to have opposite phases to each other and are incident on the group velocity dispersion portion 16.

In the example of FIG. 24, the length L₁ of the optical waveguide 4a and the length L₂ of the optical waveguide 4b are the same as each other. Meanwhile, although not shown, the length L₁ of the optical waveguide 4a and the length L₂ of the optical waveguide 4b may be different from each other. That is, a difference |L₁−L₂| between the length L₁ of the optical waveguide 4a and the length L₂ of the optical waveguide 4b and a difference between the refractive index of the optical waveguide 4a and the refractive index of the optical waveguide 4b allow a light path difference to be produced in the branched light pulses which are set to have opposite phases to each other and are incident on the group velocity dispersion portion 16.

In the short light pulse generation device 800, the first electrode 810 and the second electrode 820 apply a voltage to the optical waveguides 4a and 4b. Thereby, the refractive index of a semiconductor layer constituting the optical waveguides 4a and 4b is changed, and thus a light path difference can be produced in the branched light pulses which are set to have opposite phases to each other and are incident on the group velocity dispersion portion 16.

### 2. Second Modification Example

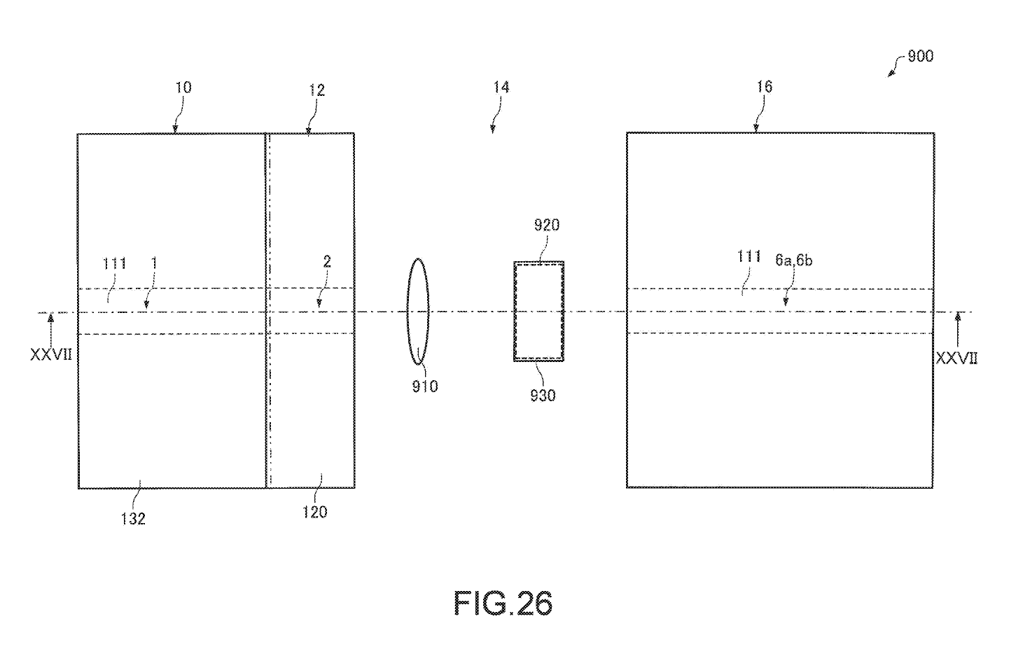

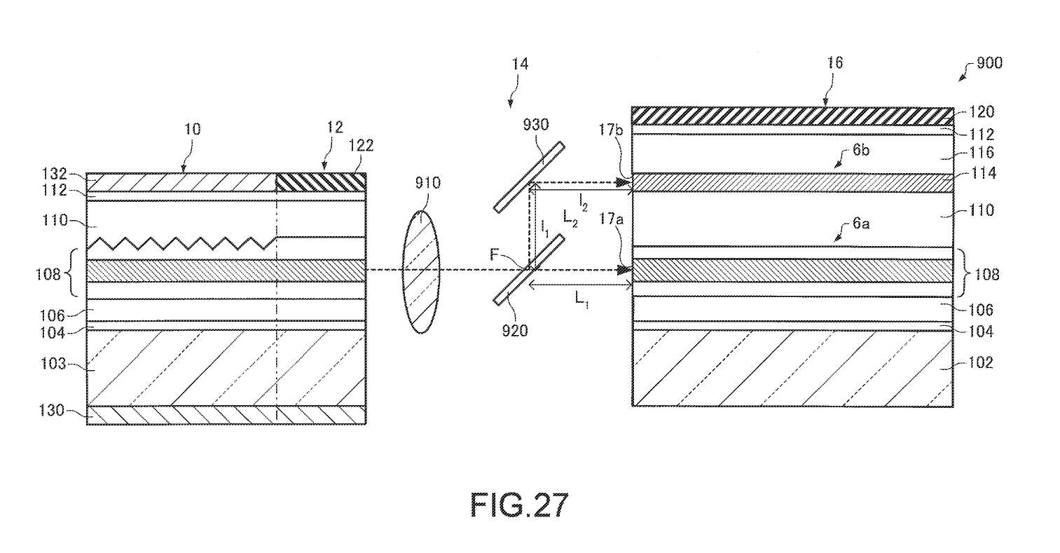

Next, a second modification example will be described. FIG. 26 is a plan view schematically illustrating a short light pulse generation device 900 according to the second modification example. FIG. 27 is a cross-sectional view schematically illustrating the short light pulse generation device 900 according to the second modification example. Meanwhile, FIG. 27 is a cross-sectional view taken along line XXVII-XXVII of FIG. 26.

In the above-mentioned short light pulse generation device 700, as shown in FIGS. 20 and 21, the light branching portion 14 is constituted by the optical waveguide 4 and the optical waveguides 4a and 4b.

On the other hand, in the short light pulse generation device 900, as shown in FIGS. 26 and 27, the light branching portion 14 is configured to include a lens 910, a beam splitter 920, and a mirror 930.

The lens 910 is a lens for guiding a light pulse emitted from the frequency chirping portion 12 to the beam splitter 920. Meanwhile, although not shown, the light pulse emitted from the frequency chirping portion 12 may be made directly incident on the beam splitter 920 without going through the lens 910.

The beam splitter 920 is an optical element for branching a light pulse into two parts. The light pulse emitted from the frequency chirping portion 12 is branched by the beam splitter 920. In the beam splitter 920, a portion of the incident light pulse can be reflected, and a portion thereof can be transmitted. Thereby, the light pulse can be branched. One of the light pulses branched by the beam splitter 920 is incident on the optical waveguide 6a of the group velocity dispersion portion 16, and the other of the light pulses branched by the beam splitter 920 is incident on the mirror 930.

The mirror 930 is an optical element for reflecting the light pulses branched by the beam splitter 920 and guiding the reflected light pulses to the optical waveguide 6b.

A difference |L₁−L₂| between a distance L₁ traveled by the light pulse before the light pulse is branched by the beam splitter 920 and then is incident on the optical waveguide 6a and a distance L₂ traveled by the light pulse before the light pulse is branched by the beam splitter 920 and then is incident on the optical waveguide 6b has the relation of Expression (6) mentioned above. Therefore, the light branching portion 14 can produce a light path difference in a plurality of branched light pulses which are set to have opposite phases to each other and are incident on the group velocity dispersion portion 16.

Here, the distance L₁ is a distance between the branch point F at which the light pulse is branched by the beam splitter 920 and the incidence plane 17a of the optical waveguide 6a, in the shown example. In addition, the distance L₂ is the sum of a distance l₁ between the branch point F and the mirror 930 and a distance l₂ between the mirror 930 and the incidence plane 17b of the optical waveguide 6b, in the shown example.

In the short light pulse generation device 900, the group velocity dispersion portion 16 is configured to include a second core layer 114 and a third cladding layer 116 in addition to the buffer layer 104, the first cladding layer 106, the core layer 108 (hereinafter, also referred to as the “first core layer 108”), the second cladding layer 110, and the cap layer 112.

The second core layer 114 is provided on the second cladding layer 110. The second core layer 114 is, for example, an i-type AlGaAs layer. The second core layer 114 is interposed between the second cladding layer 110 and the third cladding layer 116. Meanwhile, the second core layer 114 may have a quantum well structure similarly to the first core layer 108. In addition, neither the second core layer 114 nor the first core layer 108 may have a quantum well structure, but may be, for example, monolayer AlGaAs layers. In addition, the film thickness of the second core layer 114 may be the same as the film thickness of the first core layer 108, and may be different therefrom.

The third cladding layer 116 is provided on the second core layer 114. The third cladding layer 116 is, for example, an n-type AlGaAs layer.

In the shown example, the optical waveguide 6b is constituted by the second cladding layer 110, the second core layer 114, and the third cladding layer 116. The optical waveguide 6a and the optical waveguide 6b are linearly provided in the shown example. The optical waveguide 6a and the optical waveguide 6b constitute a coupled waveguide.

The optical waveguide 6a and the optical waveguide 6b constituting the group velocity dispersion portion 16 are arranged in the lamination direction of the semiconductor layers 104 to 116. In the shown example, the optical waveguide 6b is disposed above the optical waveguide 6a, and the optical waveguide 6a and the optical waveguide 6b overlap each other when seen from the lamination direction of the semiconductor layers 104 to 116.

Meanwhile, the layer structures (band structures) of the semiconductor layers 104, 106, 108, 110, 112, 114, and 116 constituting the group velocity dispersion portion 16 are not particularly limited. For example, these semiconductor layers 104 to 116 may be all formed of n-type (or p-type) semiconductor layers. In addition, for example, the first cladding layer 106 may be formed of an n-type, the first core layer 108 may be formed of an i-type, the second cladding layer 110 may be formed of a p-type, the second core layer 114 may be formed of an i-type, and the third cladding layer 116 may be formed of a p-type. In this case, an electrode connected to the first cladding layer 106 and an electrode connected to the second cladding layer 110 are provided, and thus it is possible to apply a voltage to a semiconductor layer constituting the optical waveguide 6a. In addition, for example, the first cladding layer 106 may be formed of an n-type, the first core layer 108 may be formed of an i-type, the second cladding layer 110 may be formed of an n-type, the second core layer 114 may be formed of an i-type, and the third cladding layer 116 may be formed of a p-type. In this case, an electrode connected to the second cladding layer 110 and an electrode connected to the third cladding layer 116 are provided, and thus it is possible to apply a voltage to a semiconductor layer constituting the optical waveguide 6b. In addition, for example, the first cladding layer 106 may be formed of an n-type, the first core layer 108 may be formed of an i-type, the second cladding layer 110 may be formed of a p-type, the second core layer 114 may be formed of an i-type, and the third cladding layer 116 may be formed of an n-type. In this case, an electrode connected to the first cladding layer 106 and an electrode connected to the third cladding layer 116 are provided, and thus it is possible to apply a voltage to semiconductor layers constituting the optical waveguide 6a and the optical waveguide 6b. In this manner, a voltage is applied to the semiconductor layers constituting the optical waveguides 6a and 6b, and thus a refractive index is changed by a non-linear optical effect and a propagation constant is changed. Thereby, since a group velocity dispersion value is changed, it is possible to adjust an optimum group velocity dispersion value by correcting, for example, a variation in group velocity dispersion value caused by a variation in the manufacturing of a device.

In the short light pulse generation device 900, the optical waveguide 6a and the optical waveguide 6b constituting the group velocity dispersion portion 16 are arranged in the lamination direction of the semiconductor layers 104 to 116. Thereby, the distance between the optical waveguides 6a and 6b can be controlled by the film thickness of the semiconductor layer. Therefore, the distance between the optical waveguides 6a and 6b can be controlled with a high level of accuracy. Further, for example, the first core layer 108 constituting the optical waveguide 6a and the second core layer 114 constituting the optical waveguide 6b can be formed of different materials.

### 3. Third Embodiment

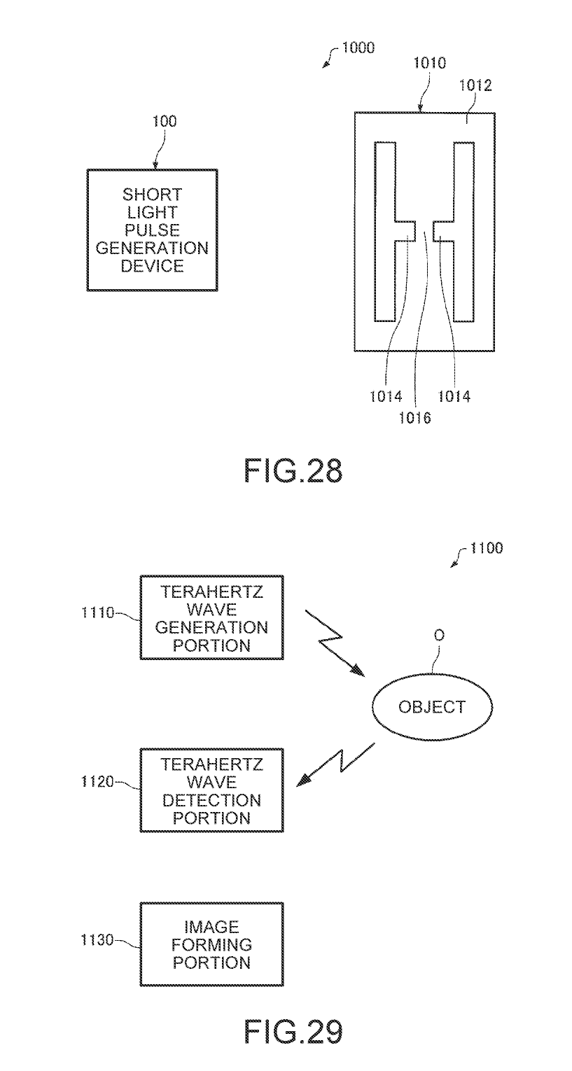

Next, a terahertz wave generation device 1000 according to a third embodiment will be described with reference to the accompanying drawings. FIG. 28 is a diagram illustrating a configuration of the terahertz wave generation device 1000 according to the third embodiment.

As shown in FIG. 28, the terahertz wave generation device 1000 includes the short light pulse generation device 100 according to the invention and a photoconductive antenna 1010. Here, as the short light pulse generation device according to the invention, a case where the short light pulse generation device 100 is used will be described.

The short light pulse generation device 100 generates a short light pulse (for example, light pulse P3 shown in FIG. 7) which is excitation light. The pulse width of the short light pulse generated by the short light pulse generation device 100 is, for example, equal to or greater than 1 fs and equal to or less than 800 fs.

The photoconductive antenna 1010 generates a terahertz wave by irradiation with the short light pulse generated in the short light pulse generation device 100. Meanwhile, the term “terahertz wave” refers to an electromagnetic wave having a frequency of equal to or greater than 100 GHz and equal to or less than 30 THz, particularly, an electromagnetic wave having a frequency of equal to or greater than 300 GHz and equal to or less than 3 THz.

In the shown example, the photoconductive antenna 1010 is a dipole-shaped photoconductive antenna (PCA). The photoconductive antenna 1010 includes a substrate 1012 which is a semiconductor substrate, and a pair of electrodes 1014 which are provided on the substrate 1012 and are disposed facing each other with a gap 1016 interposed therebetween. When irradiation with a light pulse is performed between the electrodes 1014, the photoconductive antenna 1010 generates a terahertz wave.

The substrate 1012 includes, for example, a semi-insulating GaAs (SI-GaAs) substrate and a low-temperature-grown GaAs (LT-GaAs) layer provided on the SI-GaAs substrate. The material of the electrode 1014 is, for example, Au. The distance between the pair of electrodes 1014 is not particularly limited, but is appropriately set in accordance with conditions. The distance between the pair of electrodes 1014 is, for example, equal to or greater than 1 μm and equal to or less than 10 μm.

In the terahertz wave generation device 1000, the short light pulse generation device 100 first generates a short light pulse, and emits the short light pulse toward the gap 1016 of the photoconductive antenna 1010. The gap 1016 of the photoconductive antenna 1010 is irradiated with the short light pulse emitted from the short light pulse generation device 100. In the photoconductive antenna 1010, the gap 1016 is irradiated with the short light pulse, and thus free electrons are excited. The free electrons are accelerated by applying a voltage between the electrodes 1014. Thereby, a terahertz wave is generated.

The terahertz wave generation device 1000 includes the short light pulse generation device 100, and thus it is possible to achieve a reduction in the size thereof.

### 4. Fourth Embodiment

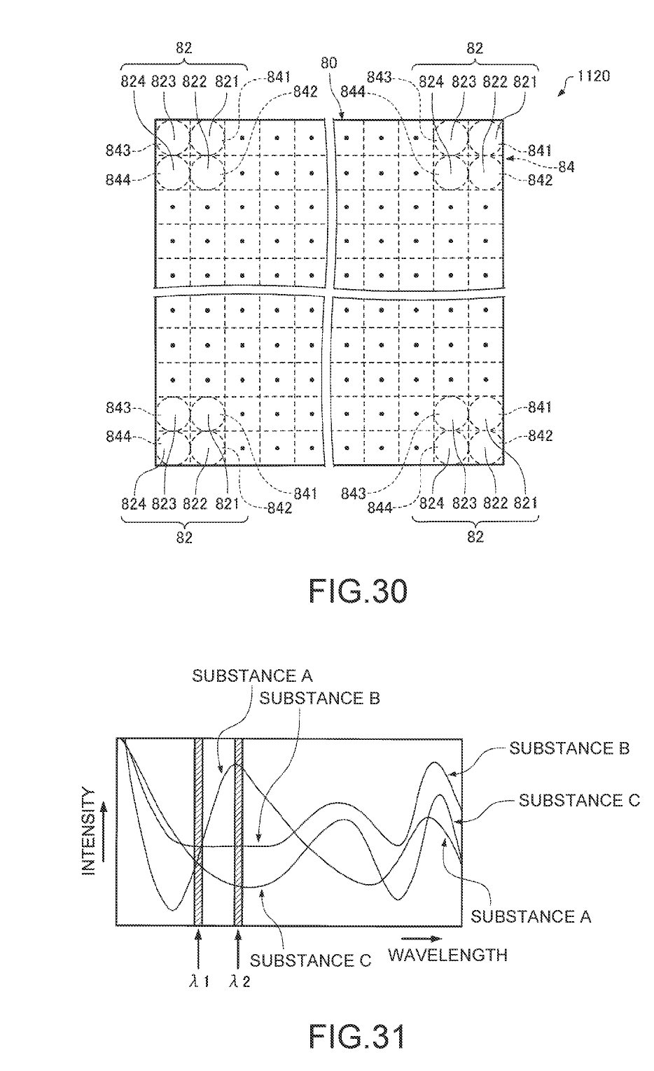

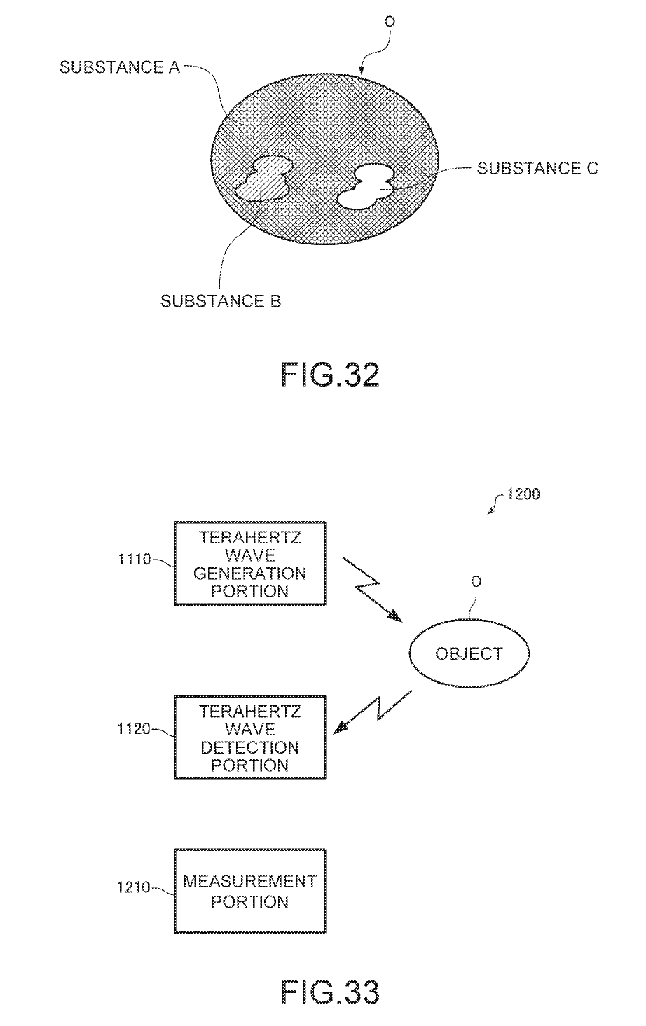

Next, an imaging device 1100 according to a fourth embodiment will be described with reference to the accompanying drawings. FIG. 29 is a block diagram illustrating the imaging device 1100 according to the fourth embodiment. FIG. 30 is a plan view schematically illustrating a terahertz wave detection portion 1120 of the imaging device 1100. FIG. 31 is a graph illustrating a spectrum in a terahertz band of an object. FIG. 32 is an image diagram illustrating the distribution of substances A, B and C of the object.

As shown in FIG. 29, the imaging device 1100 includes a terahertz wave generation portion 1110 that generates a terahertz wave, a terahertz wave detection portion 1120 that detects a terahertz wave emitted from the terahertz wave generation portion 1110 and passing through an object O or a terahertz wave reflected from the object O, and an image forming portion 1130 that generates an image of the object O, that is, image data on the basis of a detection result of the terahertz wave detection portion 1120.

As the terahertz wave generation portion 1110, a terahertz wave generation device according to the invention can be used. Here, a case will be described in which the terahertz wave generation device 1000 is used as the terahertz wave generation device according to the invention.

The terahertz wave detection portion 1120 to be used includes a filter 80 that transmits a terahertz wave having an objective wavelength and a detection portion 84 that detects the terahertz wave having an objective wavelength having passed through the filter 80, as shown in FIG. 30. In addition, the detection portion 84 to be used has, for example, a function of converting a terahertz wave into heat to detect the converted terahertz wave, that is, a function capable of converting a terahertz wave into heat to detect energy (intensity) of the terahertz wave. Such a detection portion includes, for example, a pyroelectric sensor, a bolometer or the like. Meanwhile, the configuration of the terahertz wave detection portion 1120 is not limited to the above-mentioned configuration.

In addition, the filter 80 includes a plurality of pixels (unit filter portions) 82 which are disposed two-dimensionally. That is, the respective pixels 82 are disposed in a matrix.

In addition, each of the pixels 82 includes a plurality of regions that transmit terahertz waves having wavelengths different from each other, that is, a plurality of regions in which wavelengths of terahertz waves to be transmitted (hereinafter, referred to as “transmission wavelengths”) are different from each other. Meanwhile, in the shown configuration, each of the pixels 82 includes a first region 821, a second region 822, a third region 823 and a fourth region 824.

In addition, the detection portion 84 includes a first unit detection portion 841, a second unit detection portion 842, a third unit detection portion 843 and a fourth unit detection portion 844 which are respectively provided corresponding to the first region 821, the second region 822, the third region 823 and the fourth region 824 of each pixel 82 of the filter 80. Each first unit detection portion 841, each second unit detection portion 842, each third unit detection portion 843 and each fourth unit detection portion 844 convert terahertz waves which have respectively passed through the first region 821, the second region 822, the third region 823 and the fourth region 824 of each pixel 82 into heat to detect the converted terahertz waves. Thereby, it is possible to reliably detect the terahertz waves having four objective wavelengths in the respective regions of each pixel 82.

Next, an example of use of the imaging device 1100 will be described.

First, the object O targeted for spectroscopic imaging is constituted by three substances A, B and C. The imaging device 1100 performs spectroscopic imaging on the object O. In addition, here, as an example, the terahertz wave detection portion 1120 is assumed to detect a terahertz wave reflected from the object O.

In addition, the first region 821 and the second region 822 are used in each pixel 82 of the filter 80 of the terahertz wave detection portion 1120. When the transmission wavelength of the first region 821 is set to λ1, the transmission wavelength of the second region 822 is set to λ2, the intensity of a component having the wavelength λ1 of the terahertz wave reflected from the object O is set to al, and the intensity of a component having the wavelength λ2 is set to α2, the transmission wavelength λ1 of the first region 821 and the transmission wavelength λ2 of the second region 822 are set so that differences (α2−α1) between the intensity α2 and the intensity α1 can be remarkably distinguished from each other in the substance A, the substance B and the substance C.

As shown in FIG. 31, in the substance A, the difference (α2−α1) between the intensity α2 of the component having the wavelength λ2 of the terahertz wave reflected from the object O and the intensity α1 of the component having the wavelength λ1 is set to a positive value. In addition, in the substance B, the difference (α2−α1) between the intensity α2 and the intensity α1 is set to zero. In addition, in the substance C, the difference (α2−α1) between the intensity α2 and the intensity α1 is set to a negative value.

When the spectroscopic imaging of the object O is performed by the imaging device 1100, a terahertz wave is first generated by the terahertz wave generation portion 1110, and the object O is irradiated with the terahertz wave. The terahertz wave reflected from the object O is then detected as α1 and α2 in the terahertz wave detection portion 1120. The detection results are sent out to the image forming portion 1130. Meanwhile, the irradiation of the object O with the terahertz wave and the detection of the terahertz wave reflected from the object O are performed on the entire object O.

In the image forming portion 1130, the difference (α2−α1) between the intensity α2 of the component having the wavelength λ2 of the terahertz wave having passed through the second region 822 of the filter 80 and the intensity α1 of the component having the wavelength λ1 of the terahertz wave having passed through the first region 821 is obtained on the basis of the above detection results. In the object O, a region in which the difference is set to a positive value is determined to be the substance A, a region in which the difference is set to zero is determined to be the substance B, and a region in which the difference is set to a negative value is determined to be the substance C, and the respective regions are specified.

In addition, in the image forming portion 1130, image data of an image indicating the distribution of the substances A, B and C of the object O is created as shown in FIG. 32. The image data is sent out from the image forming portion 1130 to a monitor which is not shown, and the image indicating the distribution of the substances A, B and C of the object O is displayed on the monitor. In this case, for example, using color coding, the region in which the substance A of the object O is distributed is displayed in a black color, the region in which the substance B is distributed is displayed in a gray color, and the region in which the substance C is distributed is displayed in a white color. In the imaging device 1100, in this manner, the identification of each substance constituting the object O and the distribution measurement of each substance can be simultaneously performed.

Meanwhile, the application of the imaging device 1100 is not limited to the above. For example, a person is irradiated with a terahertz wave, the terahertz wave transmitted or reflected through or from the person is detected, and a process is performed in the image forming portion 1130, and thus it is possible to discriminate whether the person carries a pistol, a knife, an illegal medicinal substance, and the like.

The imaging device 1100 includes the short light pulse generation device 100, and thus it is possible to achieve a reduction in the size thereof.

### 5. Fifth Embodiment

Next, a measurement device 1200 according to a fifth embodiment will be described with reference to the accompanying drawings. FIG. 33 is a block diagram illustrating the measurement device 1200 according to the fifth embodiment. In the measurement device 1200 according to the embodiment described below, members having the same function as the configuration members of the above-mentioned imaging device 1100 are assigned the same reference numerals and signs, and thus the detailed description thereof will be omitted.

As shown in FIG. 33, the measurement device 1200 includes a terahertz wave generation portion 1110 that generates a terahertz wave, a terahertz wave detection portion 1120 that detects a terahertz wave emitted from the terahertz wave generation portion 1110 and passing through the object O or a terahertz wave reflected from the object O, and a measurement portion 1210 that measures the object O on the basis of a detection result of the terahertz wave detection portion 1120.

Next, an example of use of the measurement device 1200 will be described. When the spectroscopic measurement of the object O is performed by the measurement device 1200, a terahertz wave is first generated by the terahertz wave generation portion 1110, and the object O is irradiated with the terahertz wave. The terahertz wave having passed through the object O or a terahertz wave reflected from the object O is then detected in the terahertz wave detection portion 1120. The detection results are sent out to the measurement portion 1210. Meanwhile, the irradiation of the object O with the terahertz wave and the detection of the terahertz wave having passed through the object O or the terahertz wave reflected from the object O are performed on the entire object O.

In the measurement portion 1210, the intensity of each terahertz wave having passed through the first region 821, the second region 822, the third region 823 and the fourth region 824 of each pixel 82 of the filter 80 is ascertained from the above detection results, and the analysis or the like of components of the object O and the distribution thereof is performed.

The measurement device 1200 includes the short light pulse generation device 100, and thus it is possible to achieve a reduction in the size thereof.

### 6. Sixth Embodiment

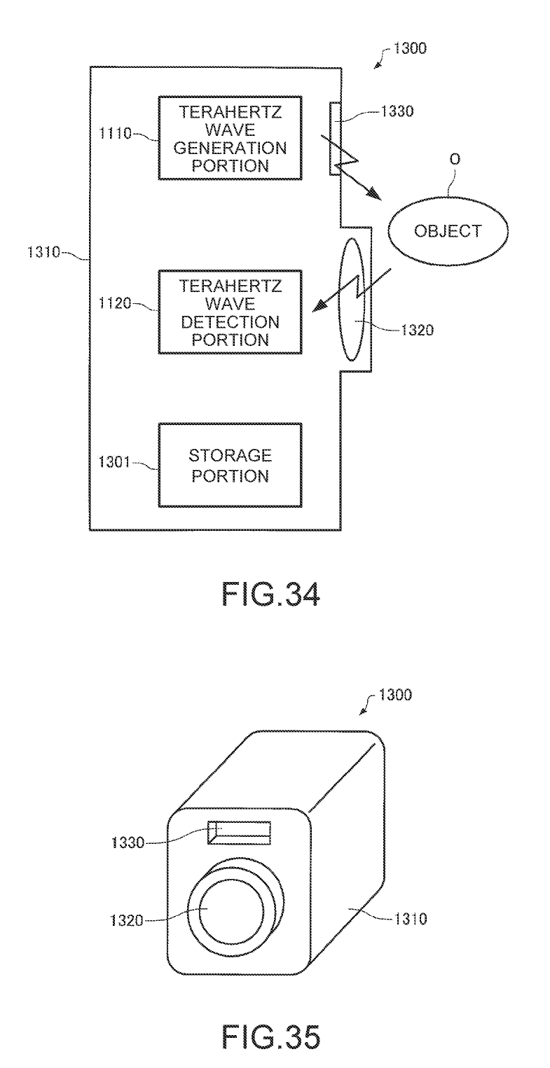

Next, a camera 1300 according to a sixth embodiment will be described with reference to the accompanying drawings. FIG. 34 is a block diagram illustrating the camera 1300 according to the sixth embodiment. FIG. 35 is a perspective view schematically illustrating the camera 1300. In the camera 1300 according to the embodiment described below, members having the same function as the configuration members of the above-mentioned imaging device 1100 are assigned the same reference numerals and signs, and thus the detailed description thereof will be omitted.

As shown in FIGS. 34 and 35, the camera 1300 includes a terahertz wave generation portion 1110 that generates a terahertz wave, a terahertz wave detection portion 1120 that detects a terahertz wave emitted from the terahertz wave generation portion 1110 and reflected from the object O or a terahertz wave passing through the object O, and a storage portion 1301. The respective portions 1110, 1120, and 1301 are contained in a housing 1310 of the camera 1300. In addition, the camera 1300 includes a lens (optical system) 1320 that converges (images) the terahertz wave reflected from the object O onto the terahertz wave detection portion 1120, and a window 1330 that emits the terahertz wave generated in the terahertz wave generation portion 1110 to the outside of the housing 1310. The lens 1320 and the window 1330 are constituted by members, such as silicon, quartz, or polyethylene, which transmit and refract the terahertz wave. Meanwhile, the window 1330 may have a configuration in which an opening is simply provided as in a slit.

Next, an example of use of the camera 1300 will be described. When the object O is imaged by the camera 1300, a terahertz wave is first generated by the terahertz wave generation portion 1110, and the object O is irradiated with the terahertz wave. The terahertz wave reflected from the object O is converged (imaged) onto the terahertz wave detection portion 1120 by the lens 1320 to detect the converged wave. The detection results are sent out to the storage portion 1301 and are stored therein. Meanwhile, the irradiation of the object O with the terahertz wave and the detection of the terahertz wave reflected from the object O are performed on the entire object O. In addition, the above detection results can also be transmitted to, for example, an external device such as a personal computer. In the personal computer, each process can be performed on the basis of the above detection results.

The camera 1300 includes the short light pulse generation device 100, and thus it is possible to achieve a reduction in the size thereof.

The above-mentioned embodiments and modification examples are illustrative examples, and are not limited thereto. For example, each of the embodiments and each of the modification examples can also be appropriately combined.

The invention includes substantially the same configurations (for example, configurations having the same functions, methods and results, or configurations having the same objects and effects) as the configurations described in the embodiments. In addition, the invention includes a configuration obtained by replacing non-essential portions in the configurations described in the embodiments. In addition, the invention includes a configuration that exhibits the same operations and effects as those of the configurations described in the embodiment or a configuration capable of achieving the same objects. In addition, the invention includes a configuration obtained by adding the configurations described in the embodiments to known techniques.

The entire disclosure of Japanese Patent Application No. 2013-036766, filed Feb. 27, 2013 is expressly incorporated by reference herein.

What is claimed is:

1. A short light pulse generation device comprising:
a light pulse generation portion that has a quantum well structure and generates a light pulse;
a frequency chirping portion that has a quantum well structure and chirps a frequency of the light pulse;
a light branching portion that branches a chirped light pulse; and
a group velocity dispersion portion that has a plurality of optical waveguides, disposed at a mode coupling distance, on which each of a plurality of the light pulses branched in the light branching portion is incident, and produces a group velocity difference depending on a wavelength with respect to a plurality of branched light pulses,
wherein light path lengths of the light pulses in a plurality of light paths before the light pulse is branched in the light branching portion and then incident on the plurality of optical waveguides of the group velocity dispersion portion are equal to each other.

2. The short light pulse generation device according to claim 1, wherein the light branching portion includes:
a first semiconductor waveguide which is made of a semiconductor material and on which the chirped light pulse is incident; and
a second semiconductor waveguide and a third semiconductor waveguide which are made of the semiconductor material and are branched from the first semiconductor waveguide, and
a length of the second semiconductor waveguide and a length of the third semiconductor waveguide are equal to each other.

3. A short light pulse generation device comprising:
a light pulse generation portion that has a quantum well structure and generates a light pulse;
a frequency chirping portion that has a quantum well structure and chirps a frequency of the light pulse;
a light branching portion that branches a chirped light pulse; and
a group velocity dispersion portion that has a plurality of optical waveguides, disposed at a mode coupling distance, on which each of a plurality of the light pulses branched in the light branching portion is incident, and produces a group velocity difference depending on a wavelength with respect to a plurality of branched light pulses,
wherein the light branching portion produces a light path difference in the plurality of branched light pulses which are set to have opposite phases to each other and are incident on the group velocity dispersion portion.

4. The short light pulse generation device according to claim 3, wherein the light branching portion includes:
a first semiconductor waveguide which is made of a semiconductor material and on which the chirped light pulse is incident; and
a second semiconductor waveguide and a third semiconductor waveguide which are made of the semiconductor material and are branched from the first semiconductor waveguide, and
the light path difference is produced by a difference between a length of the second semiconductor waveguide and a length of the third semiconductor waveguide.

5. The short light pulse generation device according to claim 3, wherein the light branching portion includes:
a first semiconductor waveguide which is made of a semiconductor material and on which the chirped light pulse is incident;
a second semiconductor waveguide and a third semiconductor waveguide which are made of the semiconductor material and are branched from the first semiconductor waveguide;
a first electrode that applies a voltage to the second semiconductor waveguide; and
a second electrode that applies a voltage to the third semiconductor waveguide.

6. A terahertz wave generation device comprising:
the short light pulse generation device according to claim 1; and
a photoconductive antenna that generates a terahertz wave by irradiation with a short light pulse generated in the short light pulse generation device.

7. A terahertz wave generation device comprising:
the short light pulse generation device according to claim 2; and
a photoconductive antenna that generates a terahertz wave by irradiation with a short light pulse generated in the short light pulse generation device.

8. A terahertz wave generation device comprising:
the short light pulse generation device according to claim 3; and
a photoconductive antenna that generates a terahertz wave by irradiation with a short light pulse generated in the short light pulse generation device.

9. A terahertz wave generation device comprising:
the short light pulse generation device according to claim 4; and
a photoconductive antenna that generates a terahertz wave by irradiation with a short light pulse generated in the short light pulse generation device.

10. A terahertz wave generation device comprising:
the short light pulse generation device according to claim 5; and
a photoconductive antenna that generates a terahertz wave by irradiation with a short light pulse generated in the short light pulse generation device.

11. A camera comprising:
the short light pulse generation device according to claim 1;
a photoconductive antenna that generates a terahertz wave by irradiation with a short light pulse generated in the short light pulse generation device;
a terahertz wave detection portion that detects the terahertz wave emitted from the photoconductive antenna and passing through an object or the terahertz wave reflected from the object; and
a storage portion that stores a detection result of the terahertz wave detection portion.

12. A camera comprising:
the short light pulse generation device according to claim 2;
a photoconductive antenna that generates a terahertz wave by irradiation with a short light pulse generated in the short light pulse generation device;
a terahertz wave detection portion that detects the terahertz wave emitted from the photoconductive antenna and passing through an object or the terahertz wave reflected from the object; and
a storage portion that stores a detection result of the terahertz wave detection portion.

13. A camera comprising:
the short light pulse generation device according to claim 3;
a photoconductive antenna that generates a terahertz wave by irradiation with a short light pulse generated in the short light pulse generation device;
a terahertz wave detection portion that detects the terahertz wave emitted from the photoconductive antenna and passing through an object or the terahertz wave reflected from the object; and
a storage portion that stores a detection result of the terahertz wave detection portion.

14. A camera comprising:
the short light pulse generation device according to claim 4;
a photoconductive antenna that generates a terahertz wave by irradiation with a short light pulse generated in the short light pulse generation device;
a terahertz wave detection portion that detects the terahertz wave emitted from the photoconductive antenna and passing through an object or the terahertz wave reflected from the object; and
a storage portion that stores a detection result of the terahertz wave detection portion.

15. A camera comprising:
the short light pulse generation device according to claim 5;
a photoconductive antenna that generates a terahertz wave by irradiation with a short light pulse generated in the short light pulse generation device;
a terahertz wave detection portion that detects the terahertz wave emitted from the photoconductive antenna and passing through an object or the terahertz wave reflected from the object; and
a storage portion that stores a detection result of the terahertz wave detection portion.

16. An imaging device comprising:
the short light pulse generation device according to claim 1;
a photoconductive antenna that generates a terahertz wave by irradiation with a short light pulse generated in the short light pulse generation device;
a terahertz wave detection portion that detects the terahertz wave emitted from the photoconductive antenna and passing through an object or the terahertz wave reflected from the object; and
an image forming portion that generates an image of the object on the basis of a detection result of the terahertz wave detection portion.

17. An imaging device comprising:
the short light pulse generation device according to claim 2;
a photoconductive antenna that generates a terahertz wave by irradiation with a short light pulse generated in the short light pulse generation device;
a terahertz wave detection portion that detects the terahertz wave emitted from the photoconductive antenna and passing through an object or the terahertz wave reflected from the object; and
an image forming portion that generates an image of the object on the basis of a detection result of the terahertz wave detection portion.

18. An imaging device comprising:
the short light pulse generation device according to claim 3;
a photoconductive antenna that generates a terahertz wave by irradiation with a short light pulse generated in the short light pulse generation device;
a terahertz wave detection portion that detects the terahertz wave emitted from the photoconductive antenna and passing through an object or the terahertz wave reflected from the object; and
an image forming portion that generates an image of the object on the basis of a detection result of the terahertz wave detection portion.

19. A measurement device comprising:
the short light pulse generation device according to claim 1;
a photoconductive antenna that generates a terahertz wave by irradiation with a short light pulse generated in the short light pulse generation device;
a terahertz wave detection portion that detects the terahertz wave emitted from the photoconductive antenna and passing through an object or the terahertz wave reflected from the object; and
a measurement portion that measures the object on the basis of a detection result of the terahertz wave detection portion.

20. A measurement device comprising:
the short light pulse generation device according to claim 3;
a photoconductive antenna that generates a terahertz wave by irradiation with a short light pulse generated in the short light pulse generation device;
a terahertz wave detection portion that detects the terahertz wave emitted from the photoconductive antenna and passing through an object or the terahertz wave reflected from the object; and
a measurement portion that measures the object on the basis of a detection result of the terahertz wave detection portion.
